(19) United States
(12) Patent Application Publication
(10) Pub. No.: US 2026/0262286 A1
(43) Pub. Date: Sep. 3, 2026

(54) LIGHT DETECTION DEVICE, METHOD FOR MANUFACTURING THE SAME, AND ELECTRONIC DEVICE

(71) Applicant: SONY SEMICONDUCTOR SOLUTIONS CORPORATION, KANAGAWA (JP)

(72) Inventor: SHOTA KITAMURA, KANAGAWA (JP)

(21) Appl. No.: 19/165,085

(22) PCT Filed: Feb. 13, 2024
(86) PCT No.: PCT/JP2024/004861

§ 371 Date: Sep. 12, 2025

(30) Foreign Application Priority Data
Mar. 31, 2023 (JP) 2023-057676

(51) Int. Cl. H10D 86/00; H04N 25/78; H10D 86/01; H10F 39/00; H10W 10/10

(52) U.S. Cl. CPC H10D 86/215; H10D 86/011; H10F 39/80373; H10F 39/80377; H10W 10/181; H04N 25/78

(57) ABSTRACT

Provided is a light detection device in which a transistor has an oxide film at the fin bottom in a bulk substrate without using an SOI substrate. The light detection device includes a first substrate portion and a second substrate portion. The first substrate portion has pixels that photoelectrically convert incident light. The second substrate portion is joined to a surface of the first substrate portion opposite to a surface on which the light is incident. Furthermore, the second substrate portion has a plurality of elements constituting a readout circuit configured to output a pixel signal based on charges output from the pixels. A pattern of an insulating film is formed on a bonding surface of the second substrate portion to the first substrate portion.

### TECHNICAL FIELD

The technique according to the present disclosure (present technique) relates to a light detection device, a method for manufacturing the same, and an electronic device including the light detection device.

### BACKGROUND ART

As a light detection device, for example, PTL 1 and PTL 2 disclose a light detection device having a three-dimensional structure that is increased in element density in the stacking direction by stacking a plurality of semiconductor substrates, each including elements such as a transistor. According to the three-dimensional structure, it is possible not only to use one plane, but also the number of elements on a plane can be increased by stacking two or three planes. Also in a finer pixel pattern, the mounting area of photoelectric conversion units and pixel transistors can be obtained.

A fin-type field-effect transistor with a gate electrode partially embedded in a semiconductor substrate is known as a transistor. In order to improve the characteristics of the fin-type field effect transistor, a structure is proposed such that a bulk substrate is replaced with an SOI (silicon on insulator) substrate with an oxide film at the fin bottom.

### CITATION LIST

### Patent Literature

[PTL 1] JP 2018-50057A

[PTL 2] WO 2020/105713

### Summary

### Technical Problem

In the fin-type field-effect transistor using the SOI substrate, the fin is formed on the oxide film and thus preferable characteristics can be obtained without leakage or the like. However, the process may be complicated by using the SOI substrate.

The present disclosure has been devised in view of such circumstances. An object of the present disclosure is to provide a light detection device, a method for manufacturing the light detection device, and an electronic device, in which a transistor has an oxide film at the fin bottom in a bulk substrate, without using the SOI substrate.

### Solution to Problem

One aspect of the present disclosure is a light detection device including: a first substrate portion having pixels that photoelectrically convert incident light, and a second substrate portion that is joined to a surface of the first substrate portion opposite to a surface on which the light is incident and has a plurality of elements constituting a readout circuit configured to output a pixel signal based on charges output from the pixels, wherein a pattern of an insulating film is formed on the bonding surface of the second substrate portion to the first substrate portion.

Another aspect of the present disclosure is method for manufacturing a light detection device, the method including: preparing a first substrate portion having pixels that photoelectrically convert incident light and a second substrate portion having a plurality of elements constituting a readout circuit configured to output a pixel signal based on charges output from the pixels; forming a pattern of an insulating film on the bonding surface of the second substrate portion to the first substrate portion; and joining the first substrate portion and the second substrate portion after forming the pattern of the insulating film.

Another aspect of the present disclosure is an electronic device including a light detection device including: a first substrate portion having pixels that photoelectrically convert incident light; and a second substrate portion that is joined to a surface of the first substrate portion opposite to a surface on which the light is incident and has a plurality of elements constituting a readout circuit configured to output a pixel signal based on charges output from the pixels, wherein a pattern of an insulating film is formed on the bonding surface of the second substrate portion to the first substrate portion.

### BRIEF DESCRIPTION OF DRAWINGS

FIG. 1 is a schematic diagram illustrating a configuration example of a light detection device according to a first embodiment of the present disclosure.

FIG. 2 is a circuit diagram showing a configuration example of the pixel unit of the light detection device 1.

FIG. 3 is a cross-sectional view of a first substrate and a second substrate where the pixel unit shown in FIG. 2 is formed.

FIG. 4 is a partial longitudinal section showing an example of the semiconductor structure of the light detection device according to the first embodiment of the present disclosure.

FIG. 5A is a plan view showing an example of the semiconductor structure of the light detection device according to the first embodiment of the present disclosure.

FIG. 5A is a plan view showing another example of the semiconductor structure of the light detection device according to the first embodiment of the present disclosure.

FIG. 6A is a cross-sectional view (1) showing the steps of a method for manufacturing the light detection device according to the first embodiment of the present disclosure.

FIG. 6B is a cross-sectional view (2) showing the steps of the method for manufacturing the light detection device according to the first embodiment of the present disclosure.

FIG. 6C is a cross-sectional view (3) showing the steps of the method for manufacturing the light detection device according to the first embodiment of the present disclosure.

FIG. 6D is a cross-sectional view (4) showing the steps of the method for manufacturing the light detection device according to the first embodiment of the present disclosure.

FIG. 6E is a cross-sectional view (5) showing the steps of the method for manufacturing the light detection device according to the first embodiment of the present disclosure.

FIG. 6F is a cross-sectional view (6) showing the steps of the method for manufacturing the light detection device according to the first embodiment of the present disclosure.

FIG. 6G is a cross-sectional view (7) showing the steps of the method for manufacturing the light detection device according to the first embodiment of the present disclosure.

FIG. 6H is a cross-sectional view (8) showing the steps of the method for manufacturing the light detection device according to the first embodiment of the present disclosure.

FIG. 7 is a cross-sectional view for explaining a state in which misalignment of an element isolation portion is prevented by a through contact region according to the first embodiment of the present disclosure.

FIG. 8A is a cross-sectional view (1) showing the steps of a method for manufacturing a light detection device according to a modification example of the first embodiment of the present disclosure.

FIG. 8B is a cross-sectional view (2) showing the steps of the method for manufacturing the light detection device according to the modification example of the first embodiment of the present disclosure.

FIG. 9A is a cross-sectional view (1) showing the steps of a method for manufacturing a light detection device according to a second embodiment of the present disclosure.

FIG. 9B is a cross-sectional view (2) showing the steps of the method for manufacturing the light detection device according to the second embodiment of the present disclosure.

FIG. 9C is a cross-sectional view (3) showing the steps of the method for manufacturing the light detection device according to the second embodiment of the present disclosure.

FIG. 9D is a cross-sectional view (4) showing the steps of the method for manufacturing the light detection device according to the second embodiment of the present disclosure.

FIG. 10A is a cross-sectional view (1) showing the steps of a method for manufacturing a light detection device according to a third embodiment of the present disclosure.

FIG. 10B is a cross-sectional view (2) showing the steps of the method for manufacturing the light detection device according to the third embodiment of the present disclosure.

FIG. 10C is a cross-sectional view (3) showing the steps of the method for manufacturing the light detection device according to the third embodiment of the present disclosure.

FIG. 11 is a partial longitudinal section showing an example of the semiconductor structure of a light detection device according to a modification example of the third embodiment of the present disclosure.

FIG. 12A is a cross-sectional view (1) showing the steps of a method for manufacturing a light detection device according to a fourth embodiment of the present disclosure.

FIG. 12B is a cross-sectional view (2) showing the steps of the method for manufacturing the light detection device according to the fourth embodiment of the present disclosure.

FIG. 12C is a cross-sectional view (3) showing the steps of the method for manufacturing the light detection device according to the fourth embodiment of the present disclosure.

FIG. 13 is a block diagram showing a configuration example of an imaging device as an electronic device to which the present technique is applied.

FIG. 14 illustrates an example of a schematic configuration of an endoscopic surgery system to which the present technique is applied.

FIG. 15 is a block diagram illustrating an example of the functional configuration of a camera head and a CCU illustrated in FIG. 14.

FIG. 16 is a block diagram illustrating an example of a schematic configuration of a vehicle control system to which the present technique is applied.

FIG. 17 is an explanatory drawing showing an example of the installation positions of a vehicle external information detection unit and an imaging unit shown in FIG. 16.

### DESCRIPTION OF EMBODIMENTS

Embodiments of the present disclosure will be described below with reference to the drawings. In the following descriptions referring to the drawings, the same or similar portions are denoted by the same or similar reference signs and redundant descriptions are omitted. However, it should be noted that the drawings are schematic and the relationship between a thickness and a planar dimension and the thickness ratio of a device and a member are different from actual relationships and ratios. Therefore, specific thicknesses and dimensions should be determined in consideration of the following description. In addition, it goes without saying that the drawings include portions having different dimensional relationships and ratios.

In the present specification, “first conductivity type” refers to one of p-type and n-type, and “second conductivity type” refers to one of p-type and n type and is different from “first conductivity type”. The semiconductor regions with “+” and “−” suffixed to “n” and “p” indicate that the semiconductor regions have relatively higher and lower impurity densities than semiconductor regions represented without “+” and “−”. However, it does not necessarily mean that semiconductor regions with the same character “n” have exactly the same impurity density.

In addition, it is to be understood that definitions of directions such as upward and downward in the following description are merely definitions provided for the sake of brevity and are not intended to limit technical ideas of the present disclosure. For example, it is obvious that when an object is observed after being rotated by 90 degrees, up-down is converted into and interpreted as left-right, and when an object is observed after being rotated by 180 degrees, up-down is interpreted as being inverted.

The advantageous effects described herein are merely exemplary and are not restrictive, and other advantageous effects may be produced.

### First Embodiment

### (Overall Configuration of Light Detection Device)

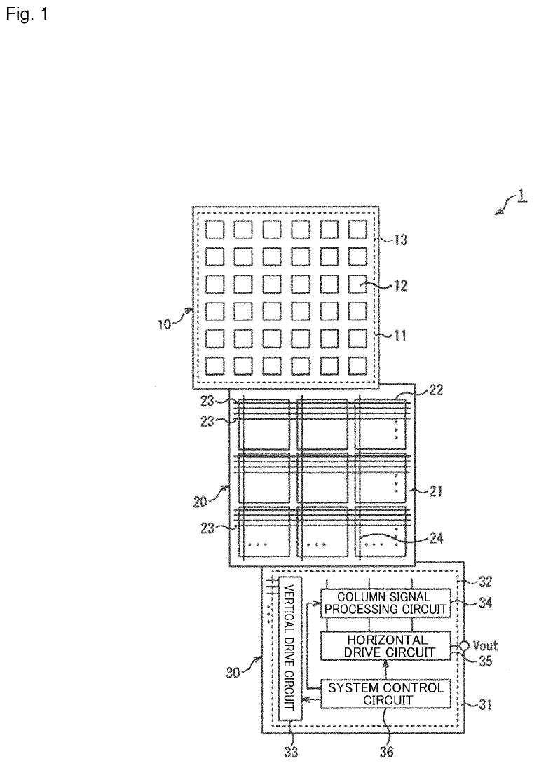

FIG. 1 is a schematic diagram illustrating a configuration example of a light detection device according to a first embodiment of the present disclosure.

As shown in FIG. 1, a light detection device 1 includes a first substrate 10, a second substrate 20, a third substrate 30. The three substrates are bonded to one another. The first substrate 10, the second substrate 20, and the third substrate 30 are stacked in this order.

The first substrate 10 has a plurality of sensor pixels 12 for photoelectric conversion on a first semiconductor substrate 11. The plurality of sensor pixels 12 are provided in a matrix form in a pixel region 13 of the first substrate 10.

The second substrate 20 has readout circuits 22, which read pixel signals based on charges output from the sensor pixels 12, on a second semiconductor substrate 21. Each of the readout circuits 22 is provided every four of the sensor pixels 12. The second substrate 20 has a plurality of pixel drive lines 23 extending in the direction.

The third substrate 30 includes a logic circuit 32 for processing a pixel signal on a third semiconductor substrate 31. The logic circuit 32 includes, for example, a vertical drive circuit 33, a column signal processing circuit 34, a horizontal drive circuit 35, and a system control circuit 36. The logic circuit 32 (specifically, the horizontal drive circuit 35) outputs an output voltage Vout for each of the sensor pixels 12 to the outside. In the logic circuit 32, for example, a low-resistance region made of silicide, which is formed using a salicide (Self Aligned Silicide) process with CoSi2 or NiSi, may be formed on the surface of an impurity diffusion region in contact with a source electrode and a drain electrode.

The vertical drive circuit 33 selects, for example, the plurality of sensor pixels 12 sequentially in rows. The column signal processing circuit 34 performs, for example, correlated double sampling (CDS) processing on the pixel signal output from each of the sensor pixels 12 in the row selected by the vertical drive circuit 33. For example, the column signal processing circuit 34 extracts the signal level of the pixel signal by performing CDS processing and holds pixel data corresponding to the amount of light received in each of the sensor pixels 12.

The horizontal drive circuit 35 sequentially outputs, for example, the pixel data held in the column signal processing circuit 34 to the outside. The system control circuit 36 controls, for example, driving of each block (the vertical drive circuit 33, the column signal processing circuit 34, and the horizontal drive circuit 35) in the logic circuit 32.

### (Circuit Configuration Example of Pixel Unit)

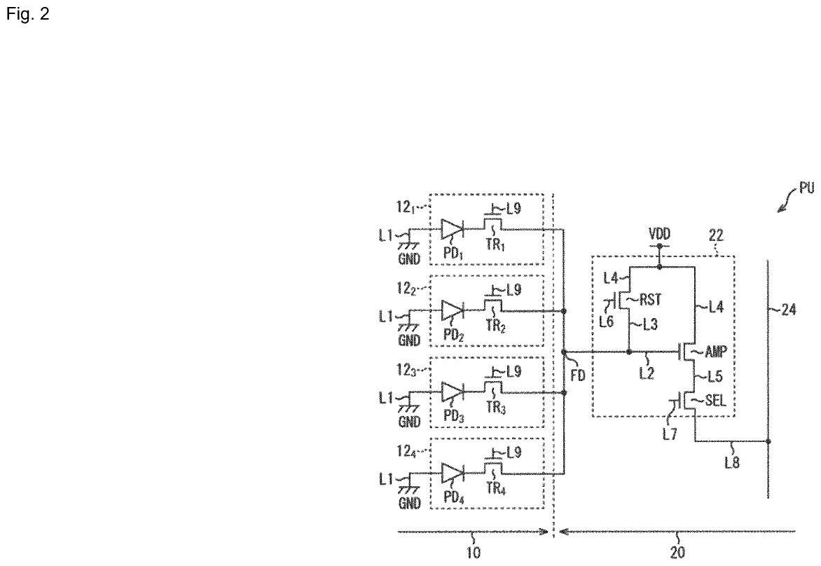

FIG. 2 is a circuit diagram showing a configuration example of a pixel unit PU of the light detection device 1.

As shown in FIG. 2, the single pixel unit PU includes the four sensor pixels 12 and the single readout circuit 22. In other words, the single readout circuit 22 is shared among the four sensor pixels 12, and the outputs of the four sensor pixels 12 are input to the shared readout circuit 22.

Each of the sensor pixels 12 includes a photodiode PD that is a photoelectric conversion element and a transfer transistor TR electrically connected to the photodiode PD.

The readout circuit 22 includes a floating diffusion FD, an amplification transistor AMP, a reset transistor RST, and a selection transistor SEL. Note that the selection transistor SEL may be omitted as necessary.

In the following description, when distinguishing among the four sensor pixels 12 connected to the single readout circuit 22, the sensor pixels 12 are denoted as sensor pixels 121 to 124 as shown in FIG. 2. The photodiodes PD and the transfer transistors TR included in the sensor pixels 121 to 124 are also denoted as photodiodes PD1 to PD4 and transfer transistors TR1 to TR4. When it is not necessary to distinguish among the four sensor pixels 12, the photodiodes PD, and the transfer transistors TR, the subscripts are omitted.

The photodiode PD performs photoelectric conversion to generate charge according to the amount of received light. The cathode of the photodiode PD is electrically connected to the source of the transfer transistor TR, and the anode of the photodiode PD is electrically connected to a reference potential line (for example, the ground). The drain of the transfer transistor TR is electrically connected to the floating diffusion FD, and the gate electrode of the transfer transistor TR is electrically connected to the pixel drive line 23.

The input end of the readout circuit 22 is the floating diffusion FD, and the source of the reset transistor RST is electrically connected to the floating diffusion FD. A predetermined power supply voltage VDD is supplied to the drain of the reset transistor RST as well as the drain of the amplification transistor AMP. The gate electrode of the reset transistor RST is electrically connected to the pixel drive line 23 (FIG. 1). The source of the amplification transistor AMP is electrically connected to the drain of the selection transistor SEL, and the gate electrode of the amplification transistor AMP is electrically connected to the source of the reset transistor RST. The source of the selection transistor SEL serves as the output terminal of the readout circuit 22 and is electrically connected to the vertical signal line 24. The gate electrode of the selection transistor SEL is electrically connected to the pixel drive line 23 (see FIG. 1).

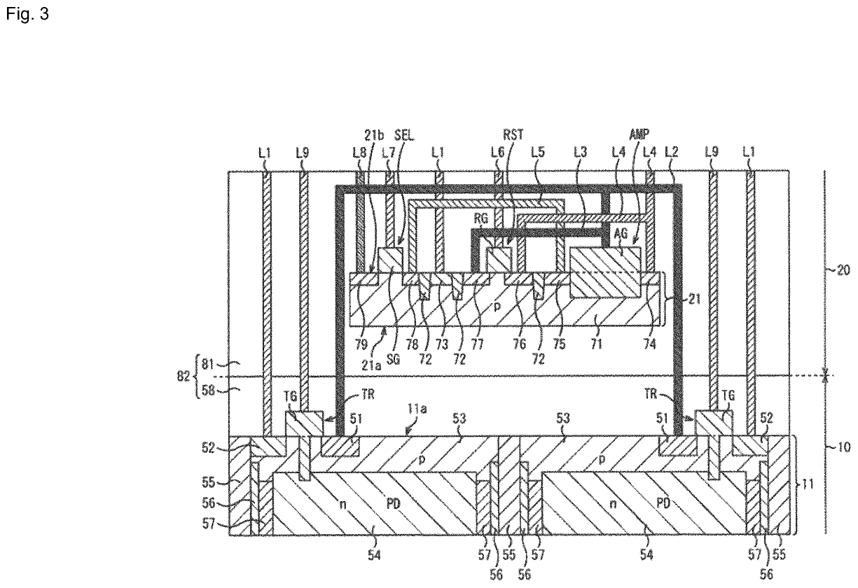

Lines L1 to L9 in FIG. 2 correspond to lines L1 to L9 in FIG. 3, which will be described later.

When the transfer transistor TR is turned on in response to a control signal supplied to the gate electrode via the pixel drive line 23 and the line L9, the transfer transistor TR transfers the charge of the photodiode PD to the floating diffusion FD. The floating diffusion FD temporarily holds the charge output from the photodiode PD through the transfer transistor TR. The reset transistor RST resets the potential of the floating diffusion FD to a predetermined potential. When the reset transistor RST is turned on, the potential of the floating diffusion FD is reset to a power supply voltage VDD.

The amplification transistor AMP generates, as a pixel signal, a signal having a voltage corresponding to the charge held in the floating diffusion FD. The amplification transistor AMP constitutes a source-follower circuit with a load MOS (not shown) as a constant current source, and outputs a pixel signal having a voltage corresponding to the level of charge generated in the photodiode PD. When the selection transistor SEL is turned on, the amplification transistor AMP amplifies the potential of the floating diffusion FD and outputs a pixel signal with a voltage corresponding to the potential to the column signal processing circuit 34 via the vertical signal line 24. The selection transistor SEL controls the output timing of a pixel signal from the readout circuit 22. When the selection transistor SEL is turned on, a pixel signal having a voltage corresponding to the level of charge held in the floating diffusion FD can be output.

The transfer transistor TR, the reset transistor RST, the amplification transistor AMP, and the selection transistor SEL include, for example, N-type MOSFETs (Metal Oxide Semiconductor Field Effect Transistors).

(Laminated Configuration Example of Pixel Unit) FIG. 3 is a cross-sectional view of the first substrate 10 and the second substrate 20 where the pixel unit PU is formed.

The cross-sectional view shown in FIG. 3 is a schematic view and is not aimed at exactly showing the actual structure. The cross-sectional view shown in FIG. 3 includes portions where the positions of the transistors and impurity diffusion layers in the horizontal direction are intentionally changed to clearly illustrate the configuration of the pixel unit PU included in the light detection device 1 in the drawing.

For example, in FIG. 3, a high-concentration n-type layer (n-type diffusion layer) 51, which is a part of the floating diffusion FD, a gate electrode TG of the transfer transistor TR, and a high-concentration p-type layer (p-type diffusion layer) 52 are arranged laterally. In an actual structure, however, the high-concentration n-type layer 51, the gate electrode TG, and the high-concentration p-type layer 52 may be arranged in the vertical direction of the drawing. In this case, one of the high-concentration n-type layer 51 and the high concentration p-type layer 52 is disposed on the near side of the drawing with the gate electrode TG interposed therebetween, and the other of the high-concentration n type layer 51 and the high-concentration p-type layer 52 is disposed on the far side of the drawing.

As shown in FIG. 3, in the light detection device 1, the first substrate 10 and the second substrate 20 are stacked to constitute a laminated body. The first substrate 10 includes the first semiconductor substrate 11, and the second substrate 20 is stacked on a front side 11a of the first semiconductor substrate 11. That is, the second substrate 20 is bonded to the first substrate 10 in face-to-back orientation.

On the front side 11a of the first semiconductor substrate 11, the transfer transistor TR is provided for each of the sensor pixels 12. The source of the transfer transistor TR is the high-concentration n-type layer 51. The high-concentration n-type layer 51 provided for each of the sensor pixels 12 is electrically connected via the line L2 and constitutes the floating diffusion FD.

The back side of the first substrate 10 opposite to the front side 11a is a light entrance surface. Accordingly, the light detection device 1 is a back-illuminated solid-state imaging device that has a color filter and an on-chip lens on the back side serving as a light entry surface. For example, the color filter and the on-chip lens are provided for each of the sensor pixels 12.

The first semiconductor substrate 11 provided in the first substrate 10 is composed of, for example, a silicon substrate. Ap-type layer 53 (hereinafter referred to as a p-well 53), which is a well layer, is provided on a part and the vicinity of the front side 11a of the first semiconductor substrate 11. An n-type layer 54 constituting the photodiode PD is provided in a region deeper than the p-well 53. The gate electrode TG of the transfer transistor TR extends from the front side 11a of the first semiconductor substrate 11 through the p-well 53 to the depth of the n-type layer 54 serving as the photodiode PD. A reference potential (e.g., a ground potential: 0 V) is supplied to the high concentration p-type layer 52, which is a contact portion of the p-well 53, via the line L1, and the potential of the p-well 53 is set to the reference potential.

The first semiconductor substrate 11 is provided with a pixel separation layer 55 that electrically separates the adjacent sensor pixels 12. The pixel separation layer 55 has, for example, a DTI (Deep Trench Isolation) structure and extends in the depth direction of the first semiconductor substrate 11. The pixel separation layer 55 is made of, for example, silicon oxide. In the first semiconductor substrate 11, a p-type layer 56 and an n-type layer 57 are provided between the pixel separation layer 55 and the photodiode PD (n-type layer 54). The p-type layer 56 is formed on the pixel separation layer 55 while the n-type layer 57 is formed on the photodiode PD.

An interlayer insulating film 58 is provided on the front side 11a of the first semiconductor substrate 11. The interlayer insulating film 58 is, for example, one of a silicon oxide film (SiO), a silicon nitride film (SiN), a silicon oxynitride of two or more of the films.

For example, the second semiconductor substrate 21 provided in the second substrate 20 is composed of a silicon substrate. The second semiconductor substrate 21 has a front side 21a facing the first substrate 10 and a back side 21b located on the opposite side from the front side 21a. In FIG. 3, the front side 21a is the lower surface and the back side 21b is the upper surface.

The second semiconductor substrate 21 includes, for example, a p-type layer 71 (hereinafter referred to as a p-well 71) that is a well layer. The amplification transistor AMP, the selection transistor SEL, and the reset transistor RST are formed on the back side 21b of the second semiconductor substrate 21.

An element isolation portion 72 is formed between the amplification transistor AMP and the reset transistor RST. A high-concentration p-type layer 73 that is a contact portion of the p-well 71 is formed between the selection transistor SEL and the reset transistor RST. The element isolation portion 72 is also formed between the selection transistor SEL and the high-concentration p-type layer 73 and between the reset transistor RST and the high-concentration p-type layer 73. The element isolation portion 72 has, for example, an STI (shallow Trench Isolation) structure. The reference potential (e.g., a ground potential: 0 V) is supplied to the high concentration p-type layer 73 via the line L1, and the potential of the p-well 71 is set to the reference potential.

The amplification transistor AMP includes a gate electrode AG, a high-concentration n-type layer 74 serving as the drain, and a high-concentration n-type layer 75 serving as the source (hereinafter referred to as a source portion 75). The gate electrode AG of the amplification transistor AMP has a structure partially embedded in the depth direction from a substrate surface (back side 21b) of the second semiconductor substrate 21.

The reset transistor RST includes a gate electrode RG, a high-concentration n-type layer 76 (hereinafter referred to as a drain portion 76) serving as the drain, and a high-concentration n-type layer 77 (hereinafter referred to as a source portion 77). The selection transistor SEL includes a gate electrode SG, a high-concentration n-type layer 78 serving as the drain, and a high-concentration n-type layer 79 serving as the source.

The gate electrode AG of the amplification transistor AMP is connected via the line L2 to the high-concentration n-type layer 51 provided for each of the sensor pixels 12 on the first semiconductor substrate 11. Moreover, the gate electrode AG of the amplification transistor AMP is also connected to the source portion 77 of the reset transistor RST via the line L3. The floating diffusion FD is composed of the high-concentration n-type layer 51 of each of the sensor pixels 12 and the source portion 77 of the reset transistor RST as well as the lines L2 and L3.

The high-concentration n-type layer 74 serving as the drain of the amplification transistor AMP and the drain portion 76 of the reset transistor RST are connected via the line L4. The predetermined power supply voltage VDD is supplied to the high concentration n-type layer 74 and the drain portion 76 via the line L4. The high-concentration n-type layer 74 and the drain portion 76 may be connected via different lines. In this case, the driving voltage of the amplification transistor AMP and the driving voltage of the reset transistor RST are set separately.

The source portion 75 of the amplification transistor AMP and the high-concentration n-type layer 78 serving as the drain of the selection transistor SEL are connected via the line L5. The source portion 75 and the high-concentration n-type layer 78 that are connected via the line L5 may be rearranged to be connected by sharing the high-concentration n-type layer 78 of the second semiconductor substrate 21 without using the line L5.

The gate electrode RG of the reset transistor RST is connected to the pixel drive line 23 via the line L6, and a driving signal for controlling the reset transistor RST is supplied from the vertical drive circuit 33.

The gate electrode SG of the selection transistor SEL is connected to the pixel drive line 23 via the line L7, and a driving signal for controlling the selection transistor SEL is supplied from the vertical drive circuit 33. The high-concentration n-type layer 79, which is the source of the selection transistor SEL, is connected to the vertical signal line 24 (FIG. 2) via the line L8, and a pixel signal having a voltage corresponding to the charge held in the floating diffusion FD is output to the vertical signal line 24 via the line L8.

The gate electrode TG of the transfer transistor TR is connected to the pixel drive line 23 via the line L9, and a driving signal for controlling the transfer transistor TR is supplied from the vertical drive circuit 33.

The second substrate 20 includes an insulating film 81 covering a front side 21a, a part of the back side 21b, and the sides of the second semiconductor substrate 21. For example, the insulating film 81 is a laminated film made of one or at least two of SiO, SiN, SiON, and SiCN. The interlayer insulating film 58 of the first substrate 10 and the interlayer insulating film 81 of the second substrate 20 are joined to each other to constitute an interlayer insulating film 82.

Any metallic material or a conductive semiconductor material can be selected as a material of the lines L1 to L9. For example, a portion extending in the stacking direction of the first substrate 10 and the second substrate 20 can be made of tungsten (W), whereas a portion extending in a direction orthogonal to the stacking direction (for example, the horizontal direction) can contain copper (Cu) or a Cu alloy composed primarily of Cu.

### <Comparative Example of First Embodiment>

In a two-stage pixel structure in which pixel transistors such as the amplification transistor AMP are formed on different substrates, the pixel transistor is a fin-type field-effect transistor. For this structure, a structure including an SOI substrate having replaced a bulk substrate and an oxide film at the fin bottom is proposed to improve the characteristics of the fin-type field effect transistor.

The structure forms a fin portion on the oxide film to improve the characteristics of the fin-type field effect transistor and thus preferable characteristics can be obtained without leakage or the like. However, the process may be complicated by using the SOI substrate. Furthermore, for the SOI substrate, high-quality control on a film thickness and crystal quality is required because the channel portion of the transistor is formed.

### <Solution to First Embodiment>

In contrast to the above problems, the first embodiment of the present disclosure has a structure in which the fin bottom has an oxide film in the bulk substrate without using an SOI substrate.

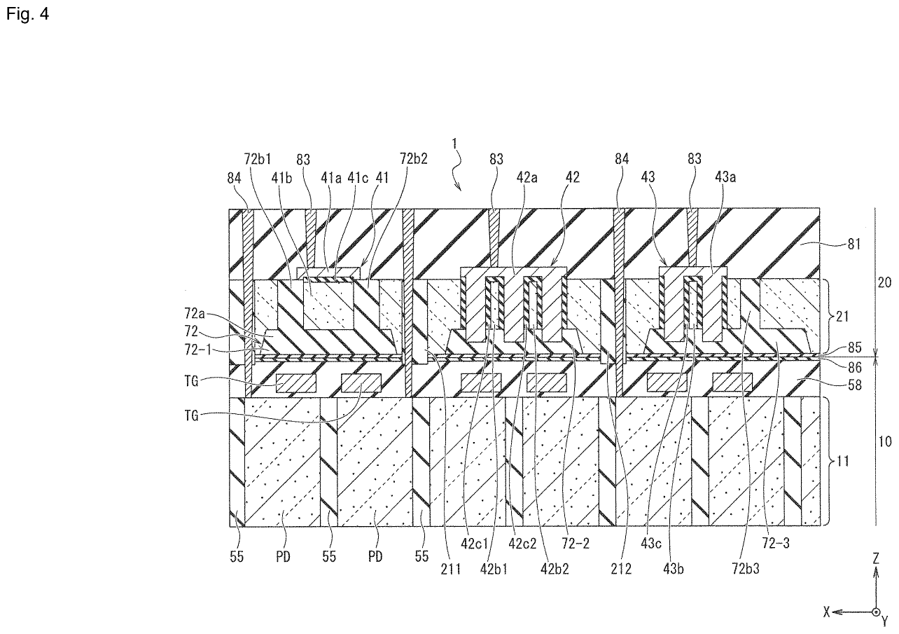

FIG. 4 is a partial longitudinal section showing an example of the semiconductor structure of the light detection device 1 according to the first embodiment of the present disclosure. In FIG. 4, the same portions as in FIG. 3 are denoted by the same reference signs, and detailed descriptions thereof are omitted.

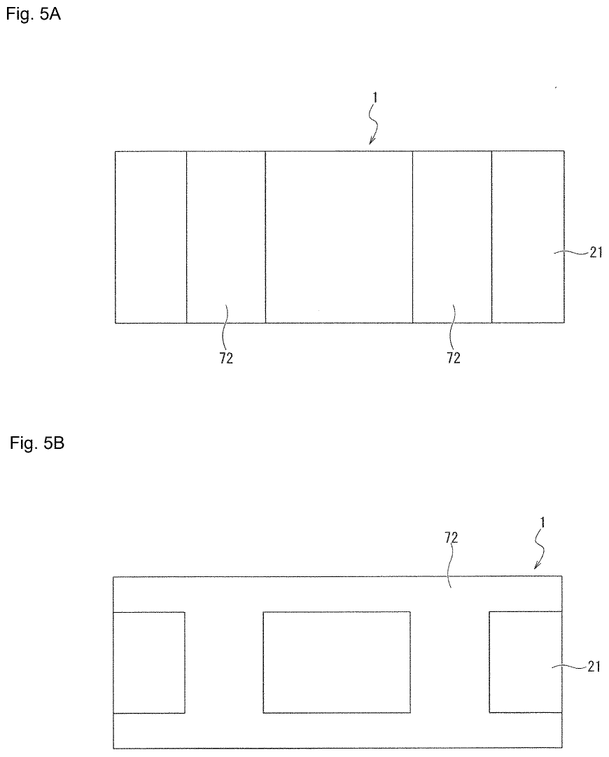

As shown in FIG. 4, a process is applied such that before the second substrate 20 is joined to the first substrate 10, as a specific structure, the element isolation portion 72 is formed in a region serving as the fin bottom of the second semiconductor substrate 21 and an oxide film is embedded in the element isolation portion 72. Thereafter, the first substrate 10 and the second substrate 20 are joined to each other. Thereafter, the same process as that of an ordinary bulk substrate is performed to form a structure as an oxide film at the fin bottom. The element isolation portion 72 may be formed like a stripe on the second semiconductor substrate 21 as shown in FIG. 5A or may be formed like an island formed like a mesh or the like.

On the second semiconductor substrate 21, three element isolation portions 72-1, 72-2, and 72-3 are arranged in a manner indicated by an arrow in FIG. 4.

Among the element isolation portions, the element isolation portion 72-1 is composed of a back side STI portion 72a formed on a bonding surface with the first substrate 10 (the back side of the second substrate 20) and front-side STI portions 72b1 and 72b2 protruding on the opposite side of the back-side STI portion 72a from the bonding surface (the direction indicated by an arrow Z in FIG. 4). The element isolation portions 72-2 and 72-3 are each composed of the back side STI portion 72a and three front-side STI portions 72b1, 72b2, and 72b3.

A planar field-effect transistor 41 is formed on the element isolation portion 72-1. The planar field-effect transistor 41 is composed of a gate electrode 41a that connects the two front-side STI portions 72b1 and 72b2 of the element isolation portion 72-1, a channel portion 41b provided between the two front-side STI portions 72b1 and 72b2, and a gate oxide film 41c provided between the gate electrode 41a and the channel portion 41b. The channel portion 41b is connected to a source portion and a drain portion that are provided in the direction indicated by an arrow Y in FIG. 4.

A fin-type field-effect transistor 42 is formed on the element isolation portion 72-2. The fin-type field-effect transistor 42 is composed of a gate electrode 42a that is formed by engraving into the three front-side STI portions 72b1, 72b2, and 72b3, element formation portions (fin portions) 42b1 and 42b2 that protrude from the element isolation portion 72-2 and are arranged in parallel at predetermined intervals, a gate oxide film 42c1 provided between the gate electrode 42a and the fin portion 42b1, and a gate electrode 42c2 provided between the gate electrode 42a and the fin portion 42b2.

That is, the gate electrode 42a and the gate oxide film 42c1 are provided over the top portion and the side portions of the fin portion 42b1. In addition, the gate electrode 42a and the gate oxide film 42c2 are provided over the top portion and the side portions of the fin portion 42b2. Thus, the gate electrode 42a can simultaneously apply a gate voltage to the top portion and the side portions of each of the fin portions 42b1 and 42b2 because of the thicknesses of the gate oxide films 42c1 and 42c2 disposed on the top portions of the fin portions 42b1 and 42b2 and the thicknesses of the gate oxide films 42c1 and 42c2 disposed on the side portions of the fin portions 42b1 and 42b2. Moreover, the fin portion 42b1 and 42b2 are connected to a source portion and a drain portion provided in the direction indicated by the arrow Y in FIG. 4.

A fin-type field-effect transistor 43 is formed on the element isolation portion 72-3. The fin-type field-effect transistor 43 is composed of a gate electrode 43a formed by engraving into the two front-side STI portions 72b1 and 72b2, a fin portion 43b protruding from the back-side STI portion 72a of the element isolation portion 72-3, and a gate oxide film 43c provided between the gate electrode 43a and the fin portion 43b.

That is, the gate electrode 43a and the gate oxide film 43c are provided over the top portion and the side portions of the fin portion 43b. Thus, the gate electrode 43a can simultaneously apply a gate voltage to the top portion and the side portions of the fin portion 43b because of the thickness of the gate oxide film 43c disposed on the top portion of the fin portion 43b and the thickness of the gate oxide film 43c disposed on the side portions of the fin portion 43b. Moreover, the fin portion 43b is connected to a source portion and a drain portion provided in the direction indicated by the arrow Y in FIG. 4.

A contact 83 is connected to each of the gate electrodes 41a, 42a, and 43a. Thus, a gate voltage is applied to each of the gate electrodes 41a, 42a, and 43a through the contact 83.

Furthermore, in the second semiconductor substrate 21, a contact through region 211 is formed between the element isolation portion 72-1 and the element isolation portion 72-2. In addition, a contact through region 212 is formed between the element isolation portions 72-2 and 72-3. A through contact 84 penetrates the contact through regions 211 and 212. The through contact 84 penetrates the interlayer insulating film 81 stacked on the second semiconductor substrate 21, the contact through regions 211 and 212, and the interlayer insulating film 58 stacked on the first semiconductor substrate 11, and reaches the high concentration n-type layer or high-concentration p-type layer that are formed on the first semiconductor substrate 11. The through contact 84 is also connected to the gate electrode TG of the transfer transistor TR.

Moreover, insulating films 85 and 86 are formed on the bonding surface between the first substrate 10 and the second substrate 20.

### (Method for Manufacturing Light Detection Device 1)

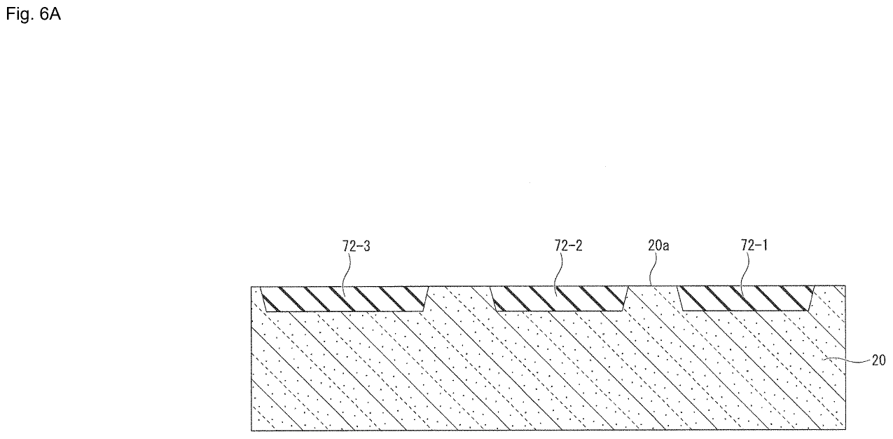

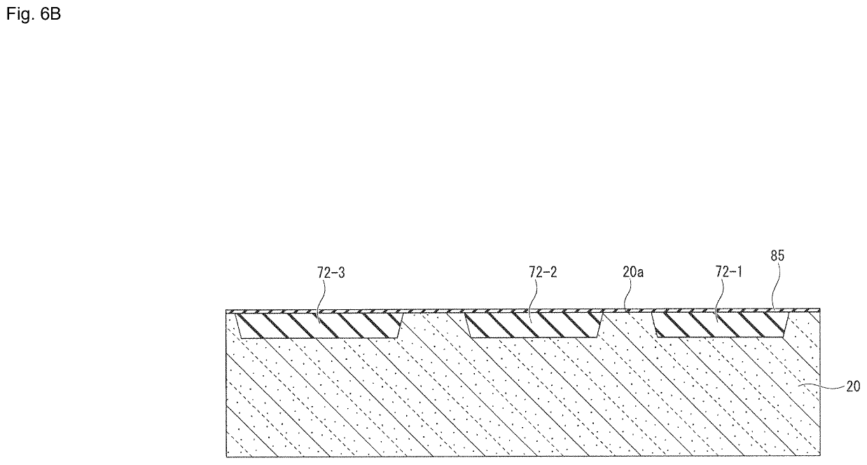

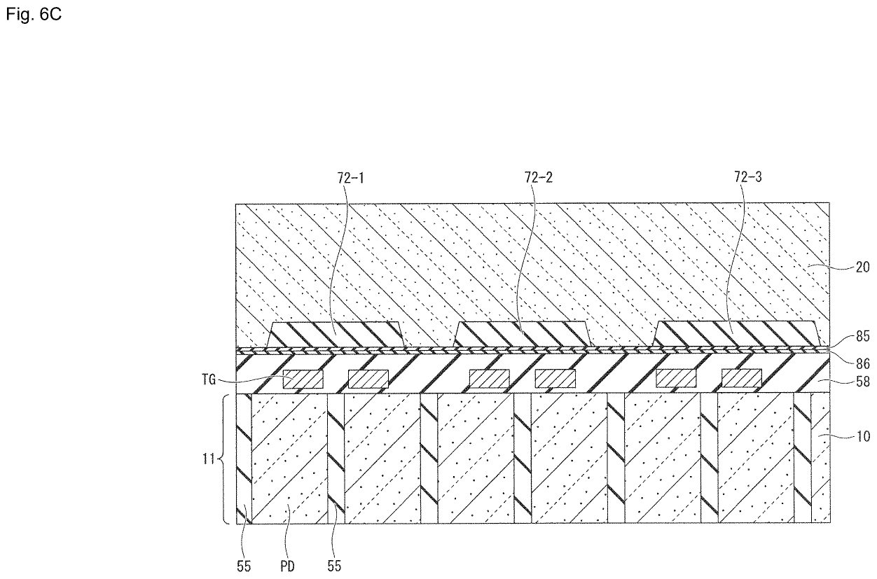

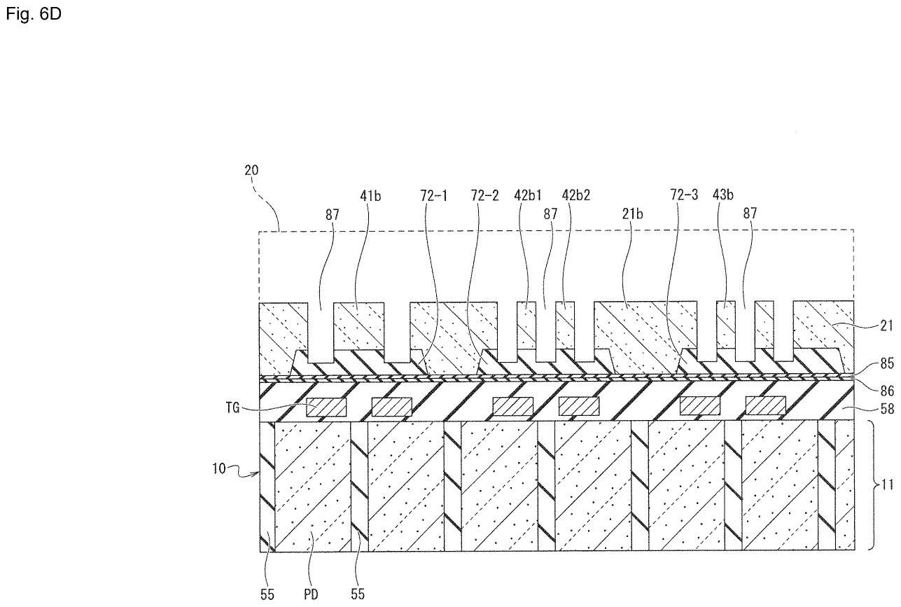

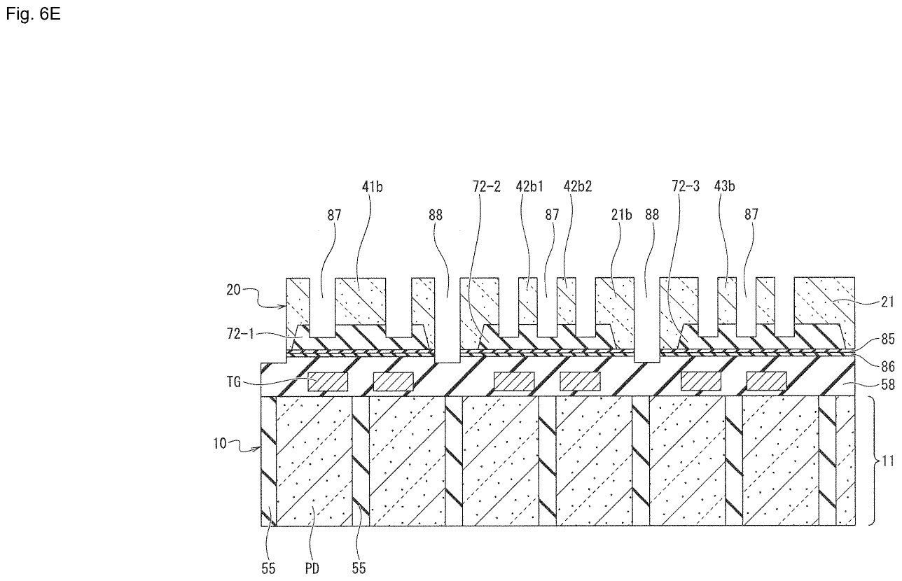

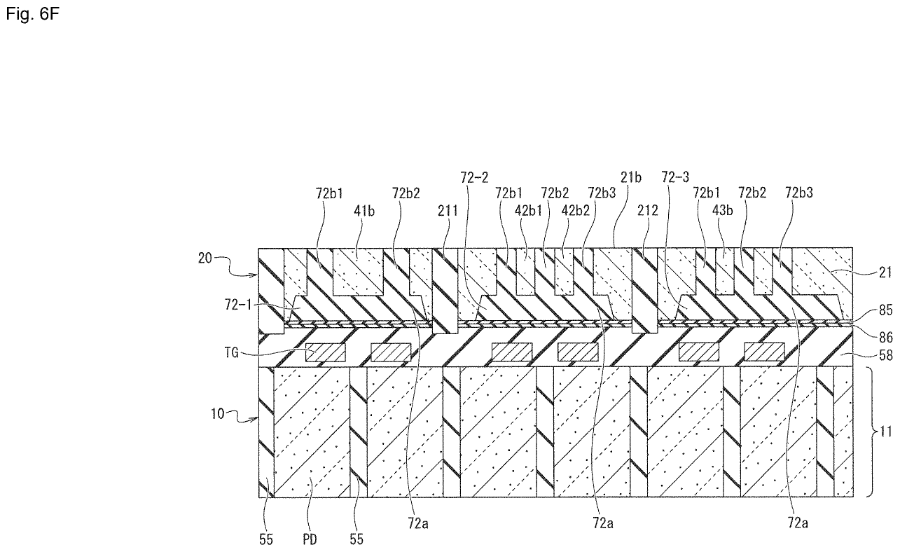

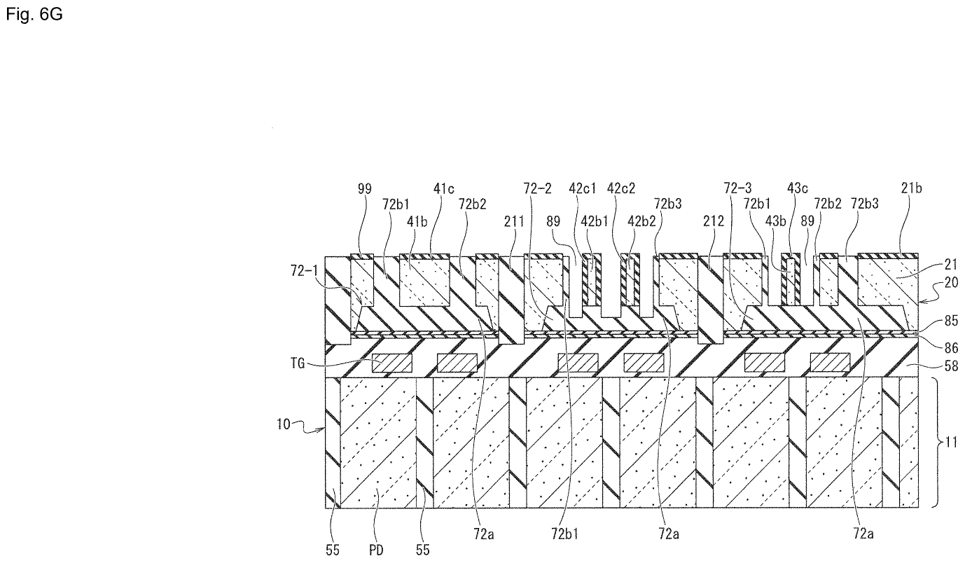

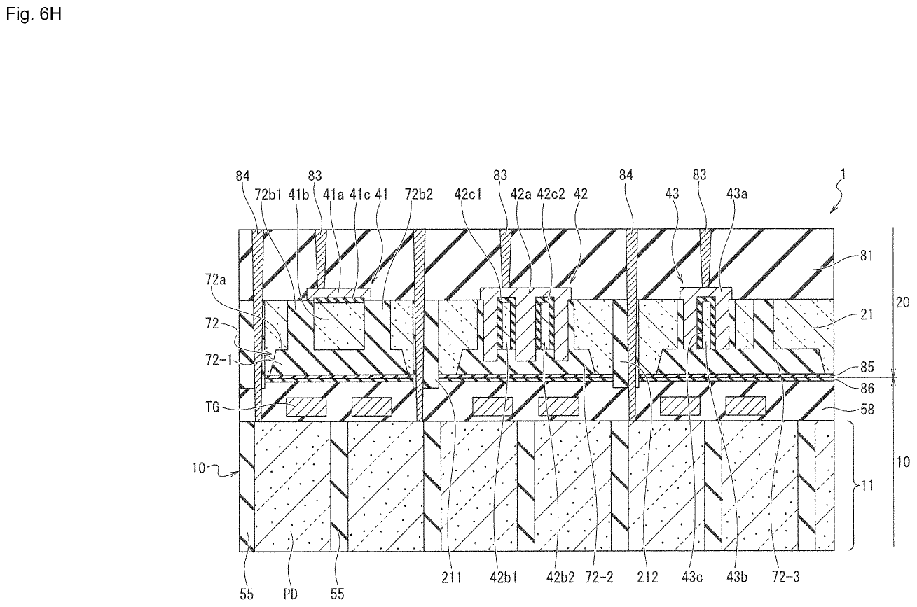

FIGS. 6A to 6H are cross-sectional views showing the steps of manufacturing the light detection device 1 according to the first embodiment of the present disclosure. The light detection device 1 is manufactured by using various devices such as a film forming device (including a chemical vapor deposition (CVD) device and a sputtering device), an ion implantation device, a heat treatment device, an etching device, a chemical mechanical polishing (CMP) First, the second substrate 20 made of silicon (Si) is prepared. In the manufacturing device, the element isolation portions 72-1, 72-2, and 72-3 are formed on the top surface, that is, a front side 20a of the second substrate 20 (FIG. 6A). After the element isolation portions 72-1, 72-2, and 72-3 are formed, an insulating film 85 is formed (FIG. 6B). As the insulating film 85, a silicon oxide film, a silicon nitride film, or a multilayer film made of materials of a silicon oxide film and a silicon nitride film is used. Note that the silicon surface may be oxidized by a thermally grown oxide film. Since the second substrate 20 is joined to the first substrate 10 in the next step, the surface of the insulating film 85 may be planarized by CMP or etch-back processing.

Subsequently, the manufacturing device reverses the second substrate 20 and bonds the second substrate 20 to the first substrate 10 (FIG. 6C). At this time, the manufacturing device planarizes the front side of the first substrate 10. The manufacturing device then forms the insulating film 86 on the front side of the first substrate 10. For the insulating film 86, a silicon nitride film or the like is used.

After the first substrate 10 and the second substrate 20 are bonded to each other, the manufacturing device reduces the thickness of the second substrate 20 to form the second semiconductor substrate 21 with a desired thickness, forms engraved portions 87 from the back side 21b of the second semiconductor substrate 21 by engraving, and forms the channel portion 41b of the planar field-effect transistor 41, the fin portions 42b1 and 42b2 of the fin-type field-effect transistor 42, and the fin portion 43b of the fin-type field-effect transistor 43 (FIG. 6D).

Subsequently, the manufacturing device forms engraved portions 88 by engraving from the back side 21b of the second semiconductor substrate 21, at the formation positions of the contact through regions 211 and 212 that allow the penetration of the through contacts 84 to the first substrate 10 (FIG. 6E). At this time, silicon etching is performed at the formation positions of the contact through regions 211 and 212 on the first substrate 10.

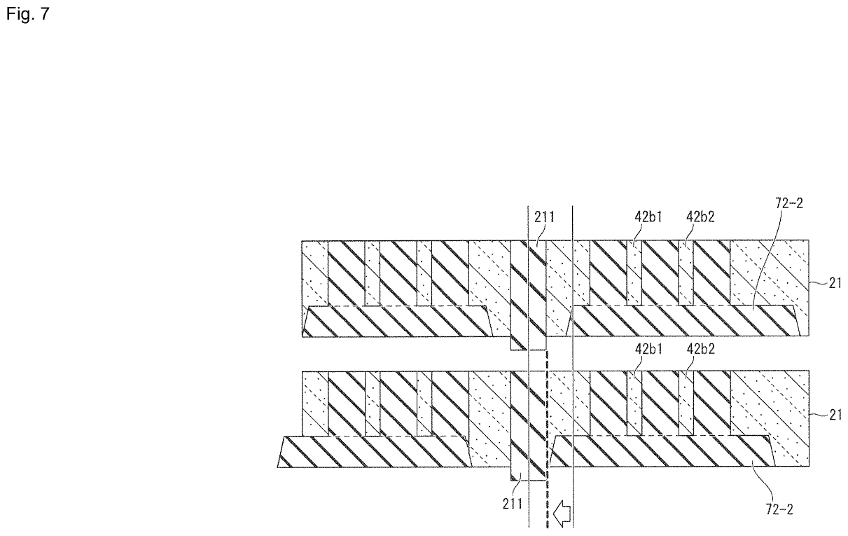

The manufacturing device then embeds an insulating film in the engraved portions 87 to form the front side STI portions 72b1, 72b2, and 72b3 of the element isolation portions 72-1, 72-2, and 72-3, and embeds an insulating film in the engraved portions 88 to form the contact through regions 211 and 212 (FIG. 6F). Thus, as shown in FIG. 7, misalignment to some extent is negligible and the fin portions 42b1 and 42b2 are not chipped.

Subsequently, as shown in FIG. 6G, the manufacturing device forms engraved portions 89 by engraving from the back side 21b of the second semiconductor substrate 21, at the formation position of the gate electrode 42a of the fin-type field-effect transistor 42 and the formation position of the gate electrode 43a of the fin-type field-effect transistor 43. In other words, portions of the front-side STI portions 72b1 and 72b3 of the element isolation portion 72-2 and the insulating film (oxide film) of the front-side STI portion 72b2 are etched (removed), and the insulating films of the front side STI portions 72b1 and 72b2 of the element isolation portion 72-3 are partially etched. Thereafter, the manufacturing device performs cleaning processing (not shown) on a processing damage part and then forms an insulating film 99 including gate oxide films 41c, 42c1, 42c2, and 43c on the back side 21b of the second semiconductor substrate 21. The gate oxide films 41c, 42c1, 42c2, and 43c can be separately formed into oxide films having multiple thicknesses. Generally, a transistor having a thick gate oxide film is operated in a high voltage system, and a transistor having a thin gate oxide film is operated in a low-voltage system. The thickness of the gate oxide film 41c of the planar field-effect transistor 41 and the thicknesses of the gate oxide films 42c1, 42c2, and 43c of the fin-type field-effect transistors 42 and 43 may be equal to each other or different from each other. The two fin portions 42b1 and 42b2 are provided for the fin-type field-effect transistor 42 while the single fin portion 43b is provided for the fin-type field-effect transistor 43. The number of fin portions is not limited thereto.

Thereafter, as shown in FIG. 6H, the manufacturing device performs gate processing with metal or polysilicon embedded in the engraved portions 89 and forms the gate electrodes 42a and 43a of the fin-type field-effect transistors 42 and 43; meanwhile, the gate electrode 41a of the planar field effect transistor 41 is formed on the top surface of the gate oxide film 41c. Subsequently, after a sidewall (not shown) is formed, the manufacturing device forms the interlayer insulating film 81 stacked on the back side 21b of the second semiconductor substrate 21. The manufacturing device forms the contacts 83 through the interlayer insulating film 81. Meanwhile, the through contacts 84 are formed through the interlayer insulating film 81, the contact through regions 211 and 212, and the interlayer insulating film 58 stacked on the first semiconductor substrate 11.

### <Function and Effect According to First Embodiment>

As described above, according to the first embodiment, considering that preferable characteristics are obtained by changing a silicon film thickness depending on a used device unlike an SOI substrate having a uniform silicon film thickness, the element isolation portions 72-1, 72-2, and 72-3 are formed on the bonding surface of the second substrate 20, which is a bulk substrate, to the first substrate 10, and then the first substrate 10 and the second substrate 20 are bonded to each other, thereby forming a silicon film having different thicknesses. Furthermore, variations can be increased by controlling the impurity profile, thereby reducing damage under the transistor layer and influence on characteristics due to an interface state.

In addition, according to the first embodiment, the fin type field effect transistor 42 is formed in the second substrate 20, allowing the gate electrode 42a of the fin-type field effect transistor 42 to apply a gate voltage to the top portions and the side portions of the fin portions 42b1 and 42b2 simultaneously in three directions, achieving a transistor with high driving capability. Furthermore, the fin-type field-effect transistor 43 is formed in the second substrate 20, allowing the gate electrode 43a of the fin-type field-effect transistor 43 to apply a gate voltage to the top portion and the side portions of the fin portion 43b simultaneously in three directions, achieving a transistor with high driving capability.

Moreover, the first embodiment can form different kinds of transistors such as the high voltage planar field-effect transistor 41 including the thick gate oxide film 41c with a high breakdown voltage and the fin-type field-effect transistors 42 and 43 on the second substrate 20.

### <Modification Example of First Embodiment>

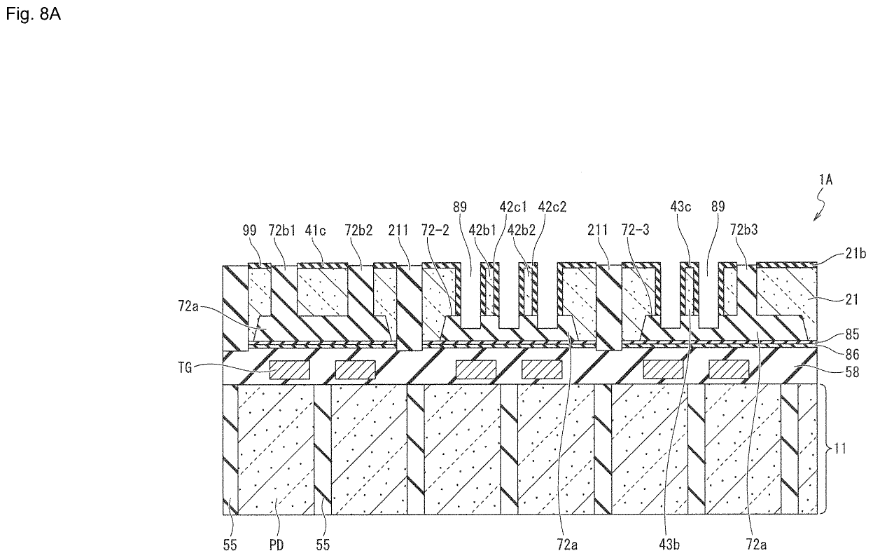

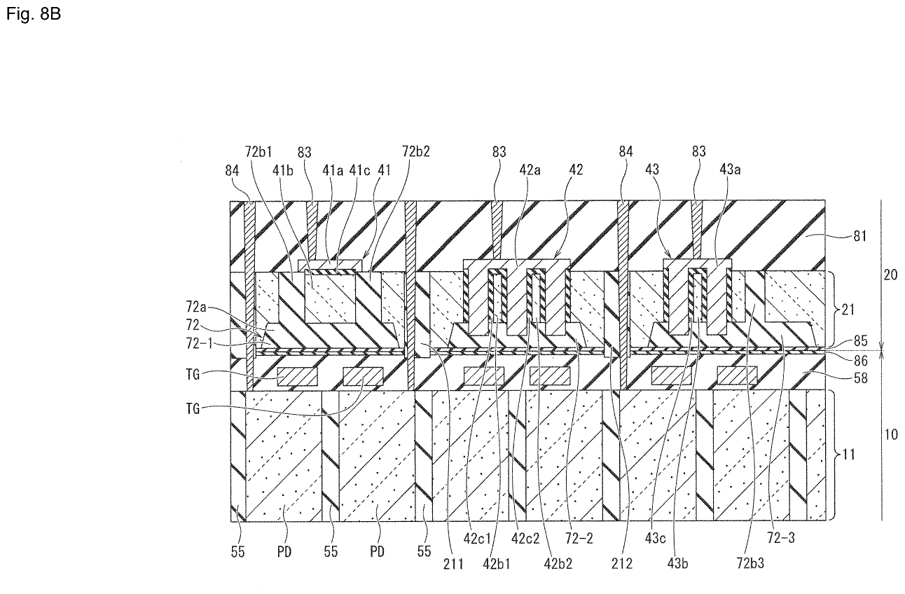

FIGS. 8A and 8B are cross-sectional views showing the steps of a method for manufacturing a light detection device 1A according to a modification example of the first embodiment of the present disclosure. In FIGS. 8A and 8B, the same portions as in FIGS. 6G and 6H are denoted by the same reference signs and detailed descriptions thereof are omitted.

As shown in FIG. 8A, the manufacturing device forms engraved portions 89 by engraving from the back side 21b of the second semiconductor substrate 21, at the formation position of the gate electrode 42a of the fin-type field-effect transistor 42 and the formation position of the gate electrode 43a of the fin-type field-effect transistor 43. In other words, all the insulating films (oxide films) of the front-side STI portions 72b1, 72b2, and 72b3 of the element isolation portion 72-2 are etched (removed), and all the insulating films of the front-side STI portions 72b1 and 72b2 of the element isolation portion 72-3 are etched. Thereafter, the manufacturing device performs cleaning processing (not shown) on a processing damage part and then forms the insulating film 99 including the semiconductor substrate 21.

Thereafter, as shown in FIG. 8B, the manufacturing device performs gate processing with metal or polysilicon embedded in the engraved portions 89 and forms the gate electrodes 42a and 43a of the fin-type field-effect transistors 42 and 43. Meanwhile, the gate electrode 41a of the planar field-effect transistor 41 is formed on the top surface of the gate oxide film 41c. Thereafter, the manufacturing device forms the interlayer insulating film 81 stacked on the back side 21b of the second semiconductor substrate 21. The manufacturing device then forms the contacts 83 through the interlayer insulating film 81. Meanwhile, the through contacts 84 are formed through the interlayer insulating film 81, the contact through regions 211 and 212, and the interlayer insulating film 58 stacked on the first semiconductor substrate 11.

### <Function and Effect According to Modification of First Embodiment>

As described above, also in the modification example of the first embodiment, the same function and effect as in the first embodiment can be obtained.

### Second Embodiment

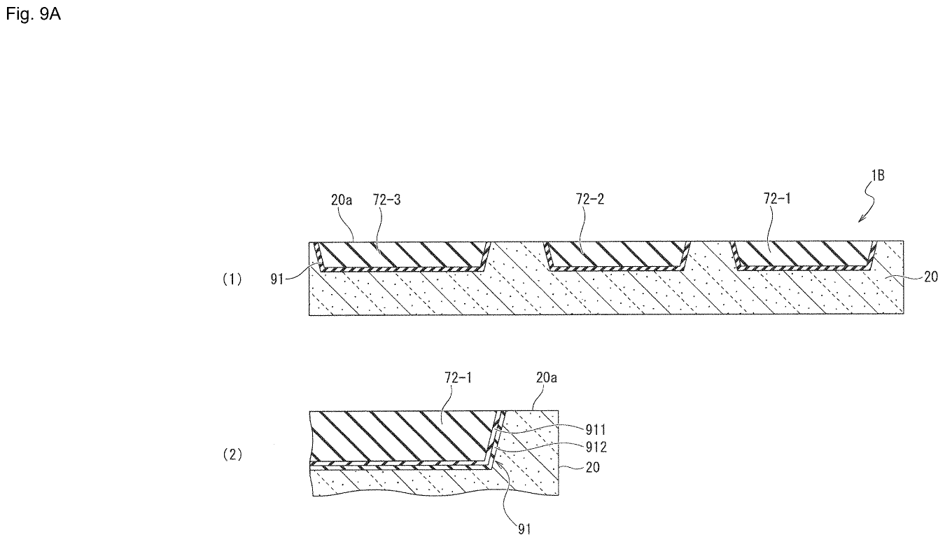

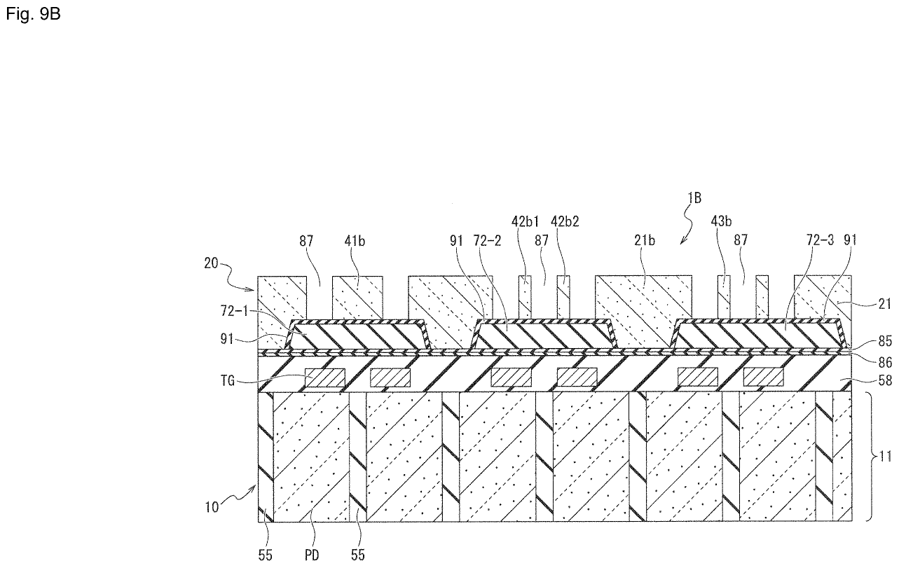

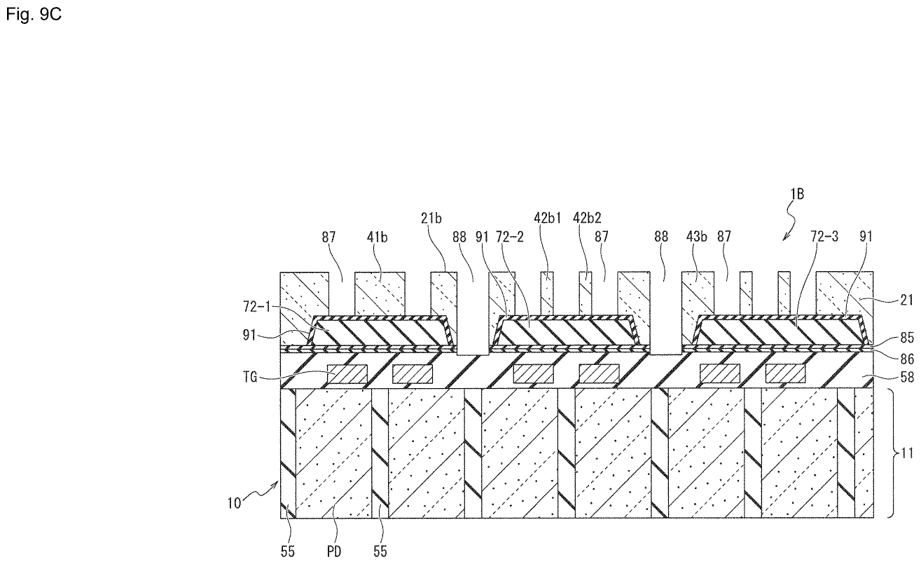

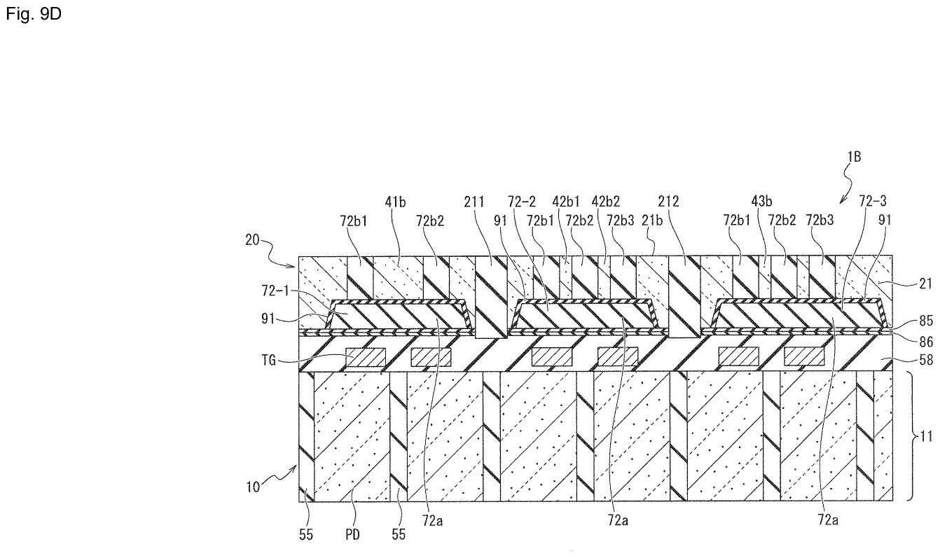

FIGS. 9A to 9D are cross-sectional views showing the steps of a method for manufacturing a light detection device 1B according to a second embodiment of the present disclosure. In FIGS. 9A to 9D, the same portions as in FIGS. 6A to 6H are denoted by the same reference signs and detailed descriptions thereof are omitted.

In a manufacturing device, element isolation portions 72-1, 72-2, and 72-3 are formed on the top surface, that is, a front side 20a of a second substrate 20 and a liner film 91 is formed around each of the element isolation portions 72-1, 72-2, and 72-3 (FIG. 9A(1)). As shown in FIG. 9A(2), the liner film 91 includes a nitride film liner 911 and an oxide film liner 912.

The manufacturing device then forms an insulating film 85 after the element isolation portions 72-1, 72-2, and 72-3 are formed. Subsequently, the manufacturing device reverses the second substrate 20 and bonds the second substrate 20 to a first substrate 10. At this time, the manufacturing device planarizes the front side of the first substrate 10. The manufacturing device then forms an insulating film 86 on the front side of the first substrate 10.

After the first substrate 10 and the second substrate 20 are bonded to each other, the manufacturing device reduces the thickness of the second substrate 20 to form a second semiconductor substrate 21 with a desired thickness, forms engraved portions 87 from a back side 21b of the second semiconductor substrate 21 by engraving, and forms a channel portion 41b of a planar field-effect transistor 41, fin portions 42b1 and 42b2 of a fin-type field-effect transistor 42, and a fin portion 43b of a fin-type field-effect transistor 43 (FIG. 9B).

Subsequently, the manufacturing device forms engraved portions 88 by engraving from the back side 21b of the second semiconductor substrate 21, at the formation positions of contact through regions 211 and 212 that allow the penetration of through contacts 84 to the first substrate 10 (FIG. 9C). At this time, silicon etching is performed at the formation positions of the contact through regions 211 and 212 on the first substrate 10.

The manufacturing device then embeds an insulating film in the engraved portions 87 to form front-side STI portions 72b1, 72b2, and 72b3 of the element isolation portions 72-1, 72-2, and 72-3, and embeds an insulating film in the engraved portions 88 to form the contact through regions 211 and 212 (FIG. 9D).

### <Function and Effect According to Second Embodiment>

As described above, according to the second embodiment, the liner film 91 is formed for each of the element isolation portions 72-1, 72-2, and 72-3 and thus acts as a stopper of silicon etching from the back side 21b of the second semiconductor substrate 21 while increasing resistance against wetness.

Furthermore, according to the second embodiment, the liner film 91 is composed of two kinds of insulating films, that is, the nitride film liner 911 and the oxide film liner 912. This can obtain the effect of a stopper film during processing after the first substrate 10 and the second substrate 20 are bonded to each other, thereby improving machining accuracy.

### Third Embodiment

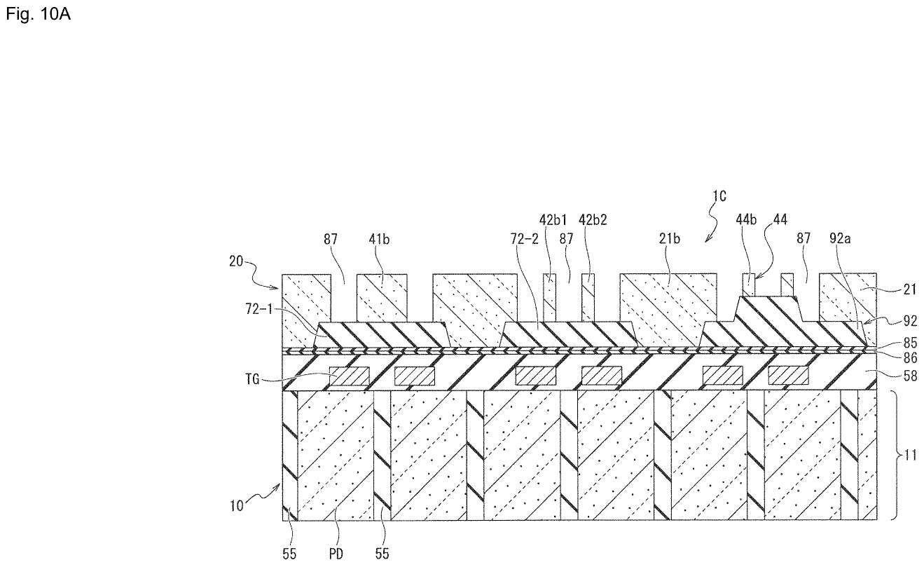

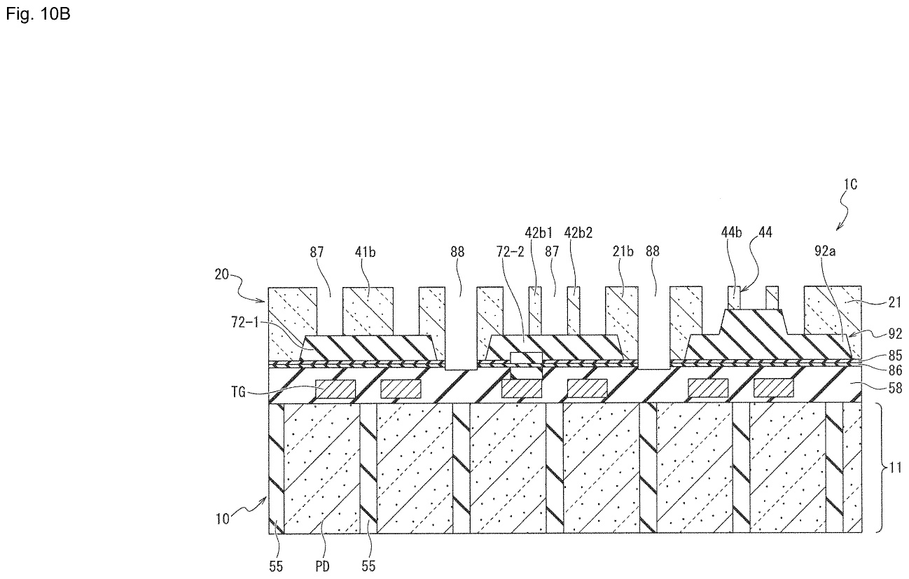

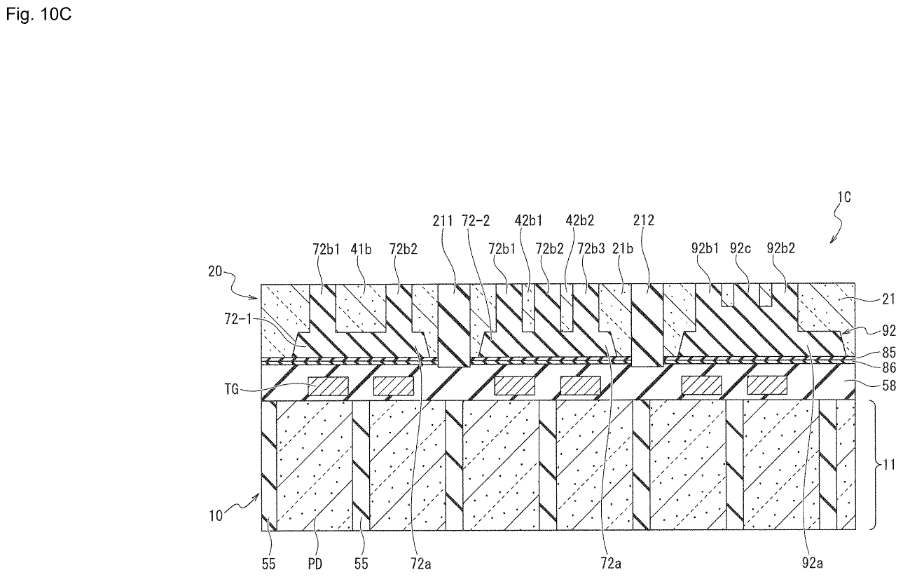

FIGS. 10A to 10C are cross-sectional views showing the steps of a method for manufacturing a light detection device 1C according to a third embodiment of the present disclosure. In FIGS. 10A to 10C, the same portions as in FIGS. 6A to 6H are denoted by the same reference signs and detailed descriptions thereof are omitted.

In a manufacturing device, as shown in FIG. 10A, element isolation portions 72-1 and 72-2 are formed on the top surface, that is, a front side 20a of a second substrate 20, and an element isolation portion 92 is formed deeper than the element isolation portions 72-1 and 72-2 in the thickness direction of a second semiconductor substrate 21. Specifically, the element isolation portion 92 has a back side STI portion 92a having a larger thickness than a back-side STI portion 72a of the element isolation portions 72-1 and 72-2.

The manufacturing device then forms an insulating film 85 after the element isolation portions 72-1, 72-2, and 92 are formed. Subsequently, the manufacturing device reverses the second substrate 20 and bonds the second substrate 20 to a first substrate 10. At this time, the manufacturing device planarizes the front side of the first substrate 10. The manufacturing device then forms an insulating film 86 on the front side of the first substrate 10.

After the first substrate 10 and the second substrate 20 are bonded to each other, the manufacturing device reduces the thickness of the second substrate 20 to form a second semiconductor substrate 21 with a desired thickness, forms engraved portions 87 from a back side 21b of the second semiconductor substrate 21 by engraving, and forms a channel portion 41b of a planar field-effect transistor 41, fin portions 42b1 and 42b2 of a fin-type field-effect transistor 42, and a fin portion 44b of a fin-type field-effect transistor 44. The fin portion 44b of the fin-type field effect transistor 44 is shorter than the fin portions 42b1 and 42b2 of the fin-type field effect transistor 42.

Subsequently, as shown in FIG. 10B, the manufacturing device forms engraved portions 88 by engraving from the back side 21b of the second semiconductor substrate 21, at the formation positions of contact through regions 211 and 212 that allow the penetration of through contacts 84 to the first substrate 10. At this time, silicon etching is performed at the formation positions of the contact through regions 211 and 212 on the first substrate 10.

As shown in FIG. 10C, the manufacturing device then embeds an insulating film in the engraved portions 87 to form front-side STI portions 72b1 and 72b2 of the element isolation portions 72-1 and 72-2 and first front-side STI portions 92b1 and 92b2 and a second front-side STI portion 92c of the element isolation portion 92, and embeds an insulating film in the engraved portions 88 to form the contact through regions 211 and 212. The liner film 91 may be formed for the element isolation portions 72-1, 72-2, and 92.

### <Function and Effect According to Third Embodiment>

As described above, according to the third embodiment, elements having different silicon film thicknesses can be formed on the second substrate 20 according to the type of elements to be formed. Thus, devices meeting various requirements can be formed on the second substrate 20.

### <Modification Example of Third Embodiment>

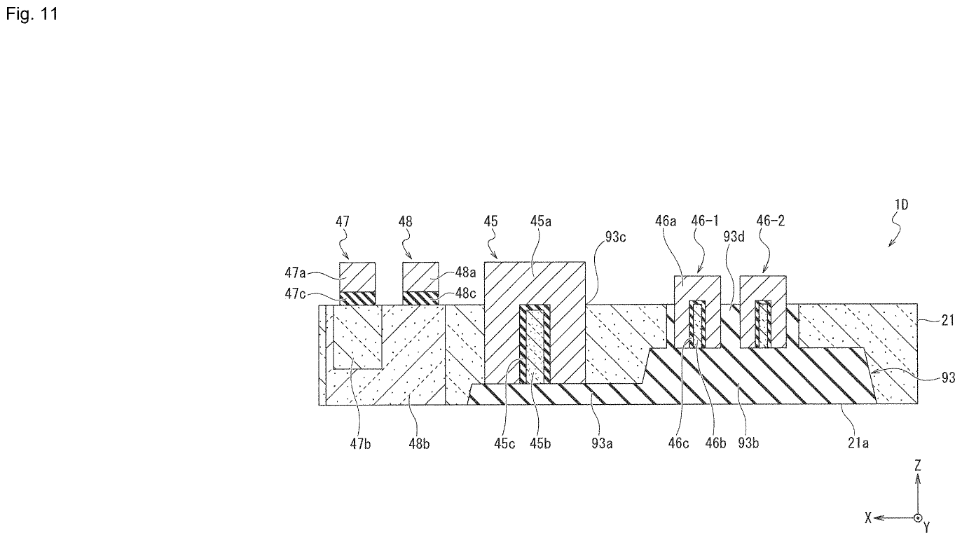

FIG. 11 is a partial longitudinal section showing an example of the semiconductor structure of a light detection device 1D according to a modification example of the FIG. 4 are denoted by the same reference signs, and detailed descriptions thereof are omitted.

As a specific structure, as shown in FIG. 11, before the second substrate 20 is bonded to the first substrate 10, an element isolation portion 93 is formed with regions having different thicknesses in a region serving as the fin bottom of the second semiconductor substrate 21. The element isolation portion 93 is formed with a first back side STI portion 93a and a second back-side STI portion 93b that are formed on the bonding surface (the back side 21a of the second semiconductor substrate 21) with the first substrate 10, a first front-side STI portion 93c protruding on the opposite side of the first back side STI portion 93a from the bonding surface (the direction indicated by an arrow Z in FIG. 11), and a second front-side STI portion 93d protruding on the opposite side of the second back side STI portion 93b from the bonding surface (the direction indicated by an arrow Z in FIG. 11). The first back-side STI portion 93a is thinner than the second back side STI portion 93b. The first front side STI portion 93c is thicker than the second front-side STI portion 93d.

A fin-type field-effect transistor 45 is formed on the first back side STI portion 93a of the element isolation portion 93. The fin-type field-effect transistor 45 is composed of a gate electrode 45a formed by engraving into the first front-side STI portion 93c, a fin portion 45b protruding from the first back side STI portion 93a, and a gate oxide film 45c provided between the gate electrode 45a and the fin portion 45b. The fin-type field-effect transistor 45 is used as, for example, a low-noise transistor with an effective gate width W.

On the second back side STI portion 93b of the element isolation portion 93, fin-type field-effect transistors 46-1 and 46-2 are formed. The fin-type field-effect transistors 46-1 and 46-2 are composed of a gate electrode 46a formed by engraving into the second front-side STI portion 93d, a fin portion 46b protruding from the second back-side STI portion 93b, and a gate oxide film 46c provided between the gate electrode 46a and the fin portion 46b. The fin-type field-effect transistors 46-1 and 46-2 are used as, for example, switching transistors in a finer pattern.

Planar field-effect transistors 47 and 48 are formed in the region of the second semiconductor substrate 21 other than the element isolation portion 93. The planar field-effect transistor 47 includes a gate electrode 47a, a channel portion 47b, and a gate oxide film 47c provided between the gate electrode 47a and the channel portion 47b. The planar field-effect transistor 48 includes a gate electrode 48a, a channel portion 48b, and a gate oxide film 48c provided between the gate electrode 48a and the channel portion 48b. The channel portion 48b has a region wider than the channel portion 47b. These planar field-effect transistors 47 and 48 are used as, for example, as high-breakdown voltage transistors including the thick gate oxide films 47c and 48c.

### <Function and Effect According to Modification Example of Third Embodiment>

As described above, according to the modification example of the third embodiment, the depth of the element isolation portion 93 is varied to obtain the effective gate width W in the first back-side STI portion 93a, thereby achieving a low-noise transistor. In the second back-side STI portion 93b, a switching transistor can be achieved in a finer pattern.

### Fourth Embodiment

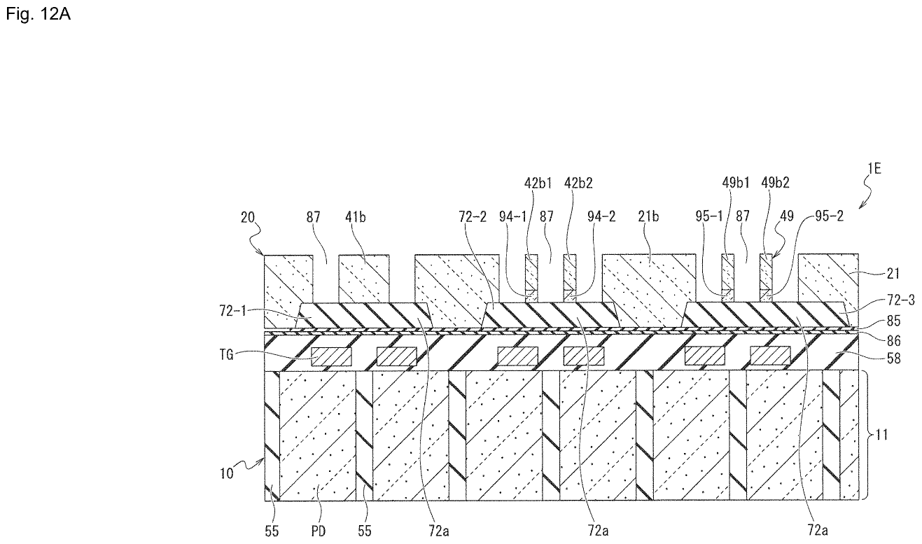

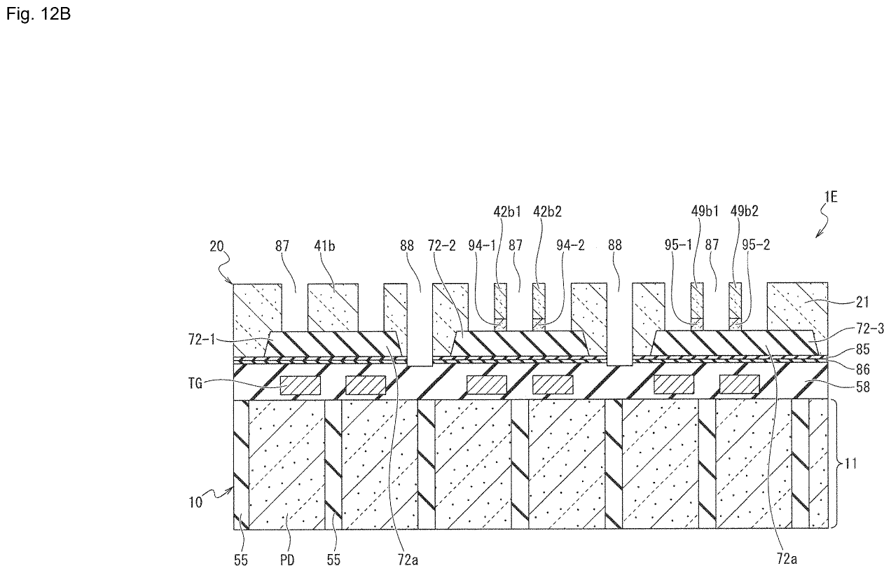

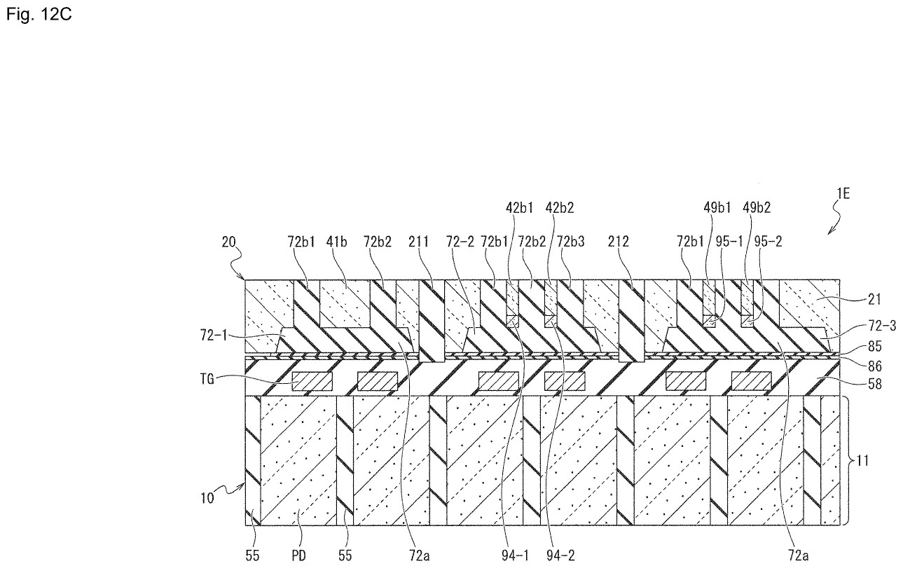

FIGS. 12A to 12C are cross-sectional views showing the steps of a method for manufacturing a light detection device 1E according to a fourth embodiment of the present disclosure. In FIGS. 12A to 12C, the same portions as in FIGS. 6A to 6H are denoted by the same reference signs and detailed descriptions thereof are omitted.

In a manufacturing device, element isolation portions 72-1, 72-2, and 72-3 are formed on the top surface, that is, a front side 20a of a second substrate 20, and impurity is injected into element isolation portions 72-2 and 72-3 that form fin-type field-effect transistors 42 and 49. The manufacturing device then forms an insulating film 85 after the element isolation portions 72-1, 72-2, and 72-3 are formed. Subsequently, the manufacturing device reverses the second substrate 20 and bonds the second substrate 20 to a first substrate 10. At this time, the manufacturing device planarizes the front side of the first substrate 10. The manufacturing device then forms an insulating film 86 on the front side of the first substrate 10.

After the first substrate 10 and the second substrate 20 are bonded to each other, the manufacturing device reduces the thickness of the second substrate 20 to form a second semiconductor substrate 21 with a desired thickness, forms engraved portions 87 from a back side 21b of the second semiconductor substrate 21 by engraving, and forms a channel portion 41b of a planar field-effect transistor 41, fin portions 42b1 and 42b2 of a fin-type field-effect transistor 42, and fin portions 49b1 and 49b2 of a fin-type field-effect transistor 49 (FIG. 12A). At this time, a doping layer 94-1 containing impurities is formed between a back-side STI portion 72a of the element isolation portion 72-2 and the fin portion 42b1, and a doping layer 94-2 containing impurities is formed between the back-side STI portion 72a of the element isolation portion 72-2 and the fin portion 42b2. Furthermore, a doping layer 95-1 containing impurities is formed between a back side STI portion 72a of the element isolation portion 72-3 and the fin portion 49b1, and a doping layer 95-2 containing impurities is formed between the back side STI portion 72a of the element isolation portion 72-3 and the fin portion 49b2.

Subsequently, the manufacturing device forms engraved portions 88 by engraving from the back side 21b of the second semiconductor substrate 21, at the formation positions of contact through regions 211 and 212 that allow the penetration of through contacts 84 to the first substrate 10 (FIG. 12B). At this time, silicon etching is performed at the formation positions of the contact through regions 211 and 212 on the first substrate 10.

The manufacturing device then embeds an insulating film in the engraved portions 87 to form front-side STI portions 72b1, 72b2, and 72b3 of the element isolation portions 72-1, 72-2, and 72-3, and embeds an insulating film in the engraved portions 88 to form the contact through regions 211 and 212 (FIG. 12C).

### <Function and Effect According to Fourth Embodiment>

As described above, according to the fourth embodiment, the doping layer 94-1 is formed between the element isolation portion 72-2 and the fin portion 42b1 and the doping layer 94-2 is formed between the element isolation portion 72-2 and the fin portion 42b2, thereby reducing the influence of the interface between the fin portions 42b1 and 42b2 and the back-side STI portion 72a.

The fourth embodiment described an example in which an impurity is injected to form the doping layers 94-1, 94-2, 95-1, and 95-2 before the first substrate 10 and the second substrate 20 are bonded to each other. An impurity may be injected from the front side 20a of the second substrate 20 after the first substrate 10 and the second substrate 20 are bonded to each other.

### Other Embodiments

The present technique has been described above in the form of the first to fourth embodiments, modification examples of the first embodiment, and modification examples of the third embodiment. It is not to be understood that the descriptions and drawings that constitute parts of the disclosure limit the present technique. It is apparent to those skilled in the art that various alternative embodiments, examples, and operation techniques fall within the range of the present technique according to the gist of the technical content disclosed according to the first to fourth embodiments, the modification example of the first embodiment, and the modification example of the third embodiment. In addition, the configurations disclosed in the first to fourth embodiments, the modification example of the first embodiment, and the modification example of the third embodiment can be combined as appropriate within a range where no contradictions arise. For example, the disclosed configurations of the different embodiments may be combined or the configurations of different modification examples of the same embodiment may be combined.

### <Example of Application to Electronic Device>

The light detection devices described above can be applied to various electronic devices, for example, an imaging device such as a digital still camera and a digital video camera, a cellular phone having an imaging function, or any other device having an imaging function.

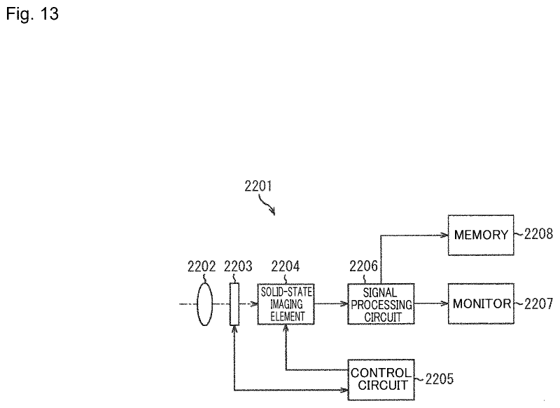

FIG. 13 is a block diagram showing a configuration example of an imaging device as an electronic device to which the present technique is applied.

The imaging device 2201 shown in FIG. 13 includes an optical system 2202, a shutter device 2203, a solid-state imaging element 2204 as a light detection device, a control circuit 2205, a signal processing circuit 2206, a monitor 2207, and two memories 2208, and the imaging device can capture still-images and moving images.

The optical system 2202 includes one or more lenses, and guides light (incident light) from an object to the solid-state imaging element 2204, and forms an image on the light receiving surface of the solid-state imaging element 2204.

The shutter device 2203 is disposed between the optical system 2202 and the solid-state imaging element 2204, and controls a light emission period and a light shielding period for the solid-state imaging element 2204 under the control of the control circuit 2205.

The solid-state imaging element 2204 includes a package including the foregoing solid-state imaging element. The solid-state imaging element 2204 accumulates signal charge for a certain period of time according to the light imaged on the light-receiving surface via the optical system 2202 and the shutter device 2203.

The signal charge accumulated in the solid-state imaging element 2204 is transferred in response to a drive signal (timing signal) supplied from the control circuit 2205.

The control circuit 2205 outputs a drive signal that controls the transfer operation of the solid-state imaging element 2204 and the shutter operation of the shutter device 2203, and drives the solid-state imaging element 2204 and the shutter device 2203.

The signal processing circuit 2206 performs various kinds of signal processing on the signal charge output from the solid-state imaging element 2204. An image (image data) obtained by the signal processing performed by the signal processing circuit 2206 is supplied to the monitor 2207 for display or supplied to the memory 2208 for storage (recording).

In the imaging device 2201 having the configuration, the light detection devices 1A, 1B, 1C, or 1D can be applied instead of the above solid-state imaging element 2204.

### <Example of Application to Endoscopic Surgery System>

The technique of the present disclosure (the present technique) can be applied to various products. For example, the technique according to the present disclosure may be applied in an endoscopic surgery system.

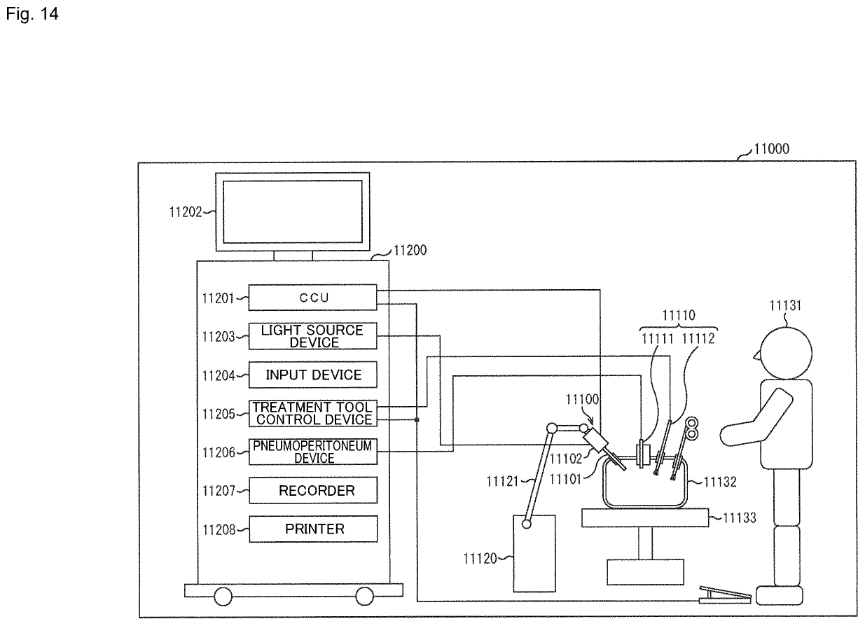

FIG. 14 illustrates an example of a schematic configuration of an endoscopic surgery system to which the technique according to the present disclosure (the present technique) is applicable.

FIG. 14 illustrates a state in which an operator (doctor) 11131 is performing a surgical operation on a patient 11132 on a patient bed 11133 by using a endoscopic surgery system 11000. As illustrated, the endoscopic surgery system 11000 includes an endoscope 11100, other surgical instruments 11110 such as a pneumoperitoneum tube 11111 and an energy treatment tool 11112, a support arm device 11120 that supports the endoscope 11100, and a cart 11200 equipped with various devices for endoscopic surgery.

The endoscope 11100 includes a lens barrel 11101 including a section to be inserted into a body cavity of the patient 11132, by a predetermined length, from the distal end of the endoscope, and a camera head 11102 connected to the proximal end of the lens barrel 11101. In the illustrated example, the endoscope 11100 is configured as a so-called rigid endoscope having the rigid lens barrel 11101. The endoscope 11100 may be configured as a so-called flexible endoscope having a flexible lens barrel.

The distal end of the lens barrel 11101 is provided with an opening where an objective lens is fit. A light source device 11203 is connected to the endoscope 11100, light generated by the light source device 11203 is guided to the distal end of the lens barrel 11101 by a light guide extending inside of the lens barrel 11101, and the light is projected to an observation target in the body cavity of the patient 11132 through the objective lens. The endoscope 11100 may be a direct-viewing endoscope, an oblique-viewing endoscope, or a side-viewing endoscope.

An optical system and an imaging element are provided inside the camera head 11102, and reflected light (observation light) from the observation target is collected on the imaging element by the optical system. The imaging element photoelectrically converts the observation light, and an electrical signal corresponding to the observation light, that is, an image signal corresponding to an observation image is thus generated. The image signal is transmitted to a camera control unit (CCU) 11201 as RAW data.

The CCU 11201 is composed of a central processing unit (CPU) and a graphics processing unit (GPU) or the like, and comprehensively controls the operations of the endoscope 11100 and a display device 11202. In addition, the CCU 11201 receives the image signal from the camera head 11102 and performs various types of image processing for displaying an image based on the image signal, for example, development processing (demosaic processing) on the image signal. The display device 11202 displays the image based on the image signal subjected to the image processing by the CCU 11201, under the control of the CCU 11201.

The light source device 11203 is composed of, for example, a light source such as a light emitting diode (LED), and supplies the endoscope 11100 with emitted light when capturing an image of a surgical site or the like.

An input device 11204 is an input interface for the endoscopic surgery system 11000. A user can input various types of information or instructions to the endoscopic surgery system 11000 via the input device 11204. For example, the user inputs instructions such as an instruction for changing imaging conditions (e.g., a type of irradiating light, a magnification, or a focal length) of the endoscope 11100.

A treatment tool control device 11205 controls driving of the energy treatment tool 11112 for cauterizing or incising a tissue, or sealing a blood vessel. A pneumoperitoneum device 11206 feeds gas into the body cavity of the patient 11132 via the pneumoperitoneum tube 11111 in order to inflate the body cavity for the purpose of securing a field of view through the endoscope 11100 and a working space of the operator. A recorder 11207 is a device capable of recording various types of information on surgery. A printer 11208 is a device capable of printing various types of information on surgery in various formats, such as text, images, and graphs.

For example, the light source device 11203 that supplies irradiation light to the endoscope 11100 to capture an image of the surgical site may be configured as a white light source configured as an LED, a laser light source, or a combination thereof. When a white light source is configured as a combination of RGB laser light sources, the output intensity and the output timing can be controlled for each color (each wavelength) with high accuracy, allowing the light source device 11203 to adjust the white balance of the image to be captured. In this case, by irradiating an observation target with the laser light from the RGB laser light sources time-divisionally and controlling driving of the imaging elements of the camera head 11102 in synchronization with the timing of light emissions, images corresponding to RGB can be captured time-divisionally. With this method, color images can be obtained without providing a color filter to the imaging element.

Furthermore, driving of the light source device 11203 may be controlled such that the intensity of output light is changed at predetermined time intervals. By controlling the driving of the imaging element of the camera head 11102 in synchronization with the timing at which the intensity of the light is changed, and time-divisionally acquiring images and combining the resultant images, an image having a high dynamic range can be generated without any so-called blocked shadow or clipped white.

The light source device 11203 may have a configuration enabled to supply light in a predetermined wavelength band corresponding to a special light observation.

In the special light observation, for example, by taking advantage of the wavelength dependency of the light absorbed by a body tissue and emitting light in a band narrower than that of the irradiating light during normal observation (that is, white light), so-called narrow band light observation (narrow-band imaging) is performed, in which a high contrast image of a predetermined tissue such as a blood vessel in the superficial layer of a mucous membrane is captured. Alternatively, in the special light observation, fluorescence observation may be performed to obtain an image by fluorescence generated by emitting excitation light. The fluorescence observation can be performed by irradiating a body tissue with the excitation light and observing fluorescence from the body tissue (autofluorescence observation), or locally injecting a reagent such as indocyanine green (ICG) to a body tissue and irradiating the body tissue with the excitation light corresponding to a fluorescence wavelength of the reagent and obtaining a fluorescence image. The light source device 11203 can be configured to supply narrow band light and/or excitation light corresponding to such special light observations.

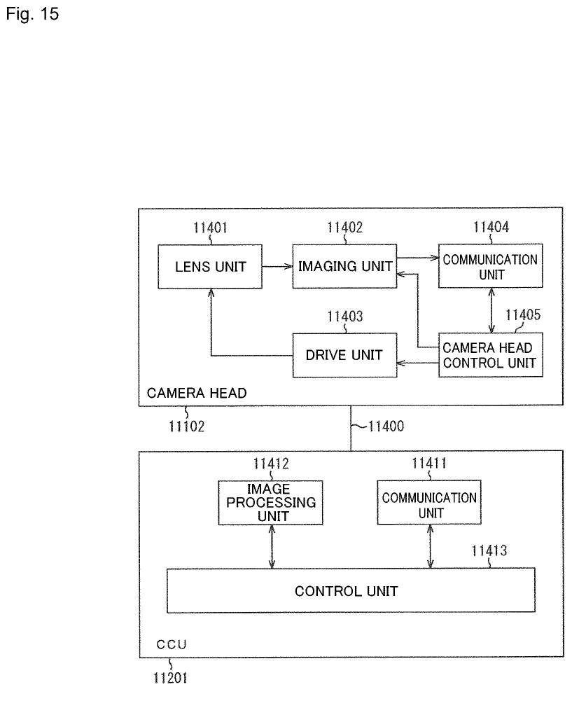

FIG. 15 is a block diagram illustrating an example of the functional configurations of the camera head 11102 and the CCU 11201 illustrated in FIG. 14.

The camera head 11102 includes a lens unit 11401, an imaging unit 11402, a drive unit 11403, a communication unit 11404, and a camera head control unit 11405. The CCU 11201 includes a communication unit 11411, an image processing unit 11412, and a control unit 11413. The camera head 11102 and the CCU 11201 are communicatively connected to each other via a transmission cable 11400.

The lens unit 11401 is an optical system provided in a connection part for connection to the lens barrel 11101. The observation light collected from the distal end of the lens barrel 11101 is guided to the camera head 11102 and enters the lens unit 11401. The lens unit 11401 is configured as a combination of a plurality of lenses including a zoom lens and a focus lens.

The imaging unit 11402 includes an imaging element. The imaging element constituting the imaging unit 11402 may be one element (a so-called single plate type) or a plurality of elements (a so-called multi-plate type). When the imaging unit 11402 is configured as a multi-plate type, for example, image signals corresponding to respective RGB are generated by the imaging elements, and a color image may be obtained by synthesizing the image signals. Alternatively, the imaging unit 11402 may be configured to include a pair of imaging elements for acquiring right-eye and left-eye image signals corresponding to three-dimensional (3D) display. The 3D display allows the operator 11131 to more accurately recognize the depth of a living tissue in a surgical site. When the imaging unit 11402 is configured as a multi-plate type, a plurality of systems of lens units 11401 may also be provided for the respective imaging elements.

The imaging unit 11402 does not always need to be provided in the camera head 11102. For example, the imaging unit 11402 may be provided immediately behind the objective lens inside of the lens barrel 11101.

The drive unit 11403 is composed of an actuator, and the zoom lens and the focus lens of the lens unit 11401 are moved by a predetermined distance along the optical axis under the control of the camera head control unit 11405. Thus, the magnification and focus of the image captured by the imaging unit 11402 can be adjusted appropriately.

The communication unit 11404 is configured as a communication device for exchanging various types of information with the CCU 11201. The communication unit 11404 transmits the image signal obtained from the imaging unit 11402 as RAW data to the CCU 11201 over the transmission cable 11400.

The communication unit 11404 receives a control signal for controlling driving of the camera head 11102 from the CCU 11201 and supplies the camera head control unit 11405 with the control signal. The control signal includes, for example, information regarding imaging conditions, such as information indicating the designation of the frame rate of a captured image, information indicating the designation of an exposure value at the time of imaging, and/or information indicating the designation of the magnification and the focus of a captured image.

The imaging conditions, such as the frame rate, the exposure value, the magnification, and the focus, may be designated by the user as appropriate, or may be automatically set by the control unit 11413 of the CCU 11201 on the basis of the acquired image signal. In the latter case, the endoscope 11100 has a so-called auto exposure (AE) function, a so-called auto focus (AF) function, and a so-called auto white balance (AWB) function.

The camera head control unit 11405 controls the driving of the camera head 11102 based on a control signal received from the CCU 11201 via the communication unit 11404.

The communication unit 11411 is composed of a communication device that transmits and receives various kinds of information to and from the camera head 11102. The communication unit 11411 receives an image signal transmitted via the transmission cable 11400 from the camera head 11102.

The communication unit 11411 transmits the control signal for controlling the driving of the camera head 11102 to the camera head 11102. The image signal and the control signal can be transmitted through electric communications or optical communications or the like.

The image processing unit 11412 performs various types of image processing on the image signal that is the RAW data transmitted from the camera head 11102.

The control unit 11413 performs various types of control for causing the endoscope 11100 to capture images of the surgical site or the like, and for displaying the captured image obtained by capturing images of a surgical site or the like. For example, the control unit 11413 generates control signals for controlling the driving of the camera head 11102.

In addition, the control unit 11413 causes the display device 11202 to display a captured image of a surgical site or the like, on the basis of the image signal resultant of the image processing performed by the image processing unit 11412. At this point, the control unit 11413 may recognize various objects in the captured image using various image recognition techniques. For example, the control unit 11413 can recognize a surgical instrument such as forceps, a specific biological region, bleeding, mist or the like during the use of the energy treatment tool 11112 by detecting, for example, the shape and color of the edge of an object included in the captured image. When the control unit 11413 causes the display device 11202 to display the captured image, the control unit 11413 may display various types of surgery support information superimposed on the image of the surgical site by using the result of recognition. The superimposed surgery support information is displayed and is presented to the operator 11131, can reliably perform a surgical operation.

The transmission cable 11400 that connects the camera head 11102 and the CCU 11201 is an electrical signal cable that supports electrical signal communication, an optical fiber that supports optical communication, or a composite cable thereof.

Although wired communication is performed using the transmission cable 11400 in the illustrated example, radio communications may be performed between the camera head 11102 and the CCU 11201.

An example of an endoscopic surgery system to which the technique according to the present disclosure is applicable has been described thus. The technique according to the present disclosure may be applied to, for example, the endoscope 11100, the imaging unit 11402 of the camera head 11102, the image processing unit 11412 of the CCU 11201, and the like among the components described above. Specifically, the light detection device 1A of FIG. 1 can be applied to the imaging unit 10402.

Here, the endoscopic surgery system has been described as an example. The technique according to the present disclosure may be applied to other systems, such as a microscopic surgery system.

### <Application to Moving Body>

The technique of the present disclosure (the present technique) can be applied to various products. For example, the technique according to the present disclosure may be implemented as a device equipped in any type of moving body such as an automobile, an electric vehicle, a hybrid electric vehicle, a motorcycle, a bicycle, a personal mobility device, an airplane, a drone, a ship, and a robot.

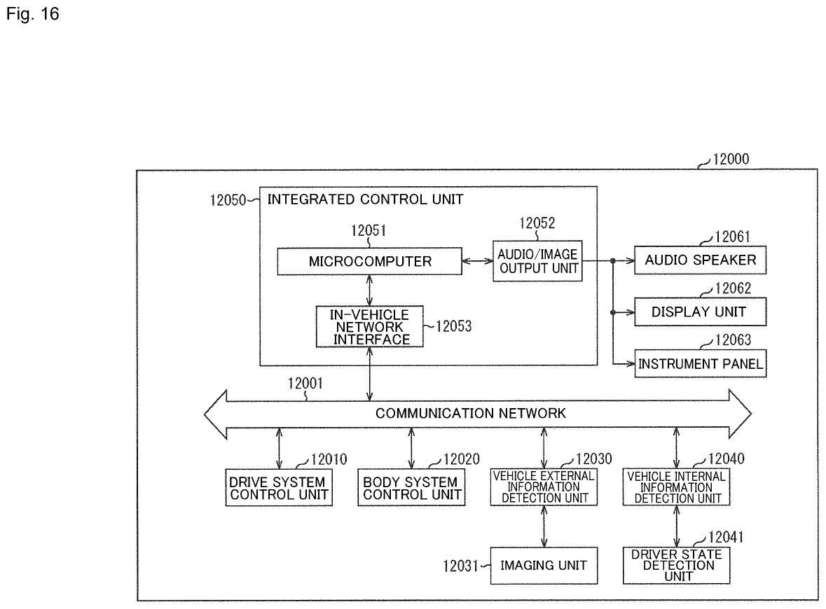

FIG. 16 is a block diagram illustrating a schematic configuration example of a vehicle control system, which is an example of a moving body control system to which the technique according to the present disclosure can be applied. The vehicle control system 12000 includes a plurality of electronic control units connected thereto via a communication network 12001. In the example illustrated in FIG. 16, the vehicle control system 12000 includes a drive system control unit 12010, a body system control unit 12020, a vehicle external information detection unit 12030, a vehicle internal information detection unit 12040, and an integrated control unit 12050. In addition, as a functional configuration of the integrated control unit 12050, a microcomputer 12051, an audio/image output unit 12052, and an in-vehicle network interface (I/F) 12053 are illustrated.

The drive system control unit 12010 controls the operation of a device related to a vehicle drive system according to various programs. For example, the drive system control unit 12010 functions as control devices for a driving force generation device for generating driving force for the vehicle, such as an internal combustion engine or a driving motor, a driving force transmission mechanism for transmitting driving force to wheels, a steering mechanism for adjusting a turning angle of the vehicle, and a braking device that generates braking force for the vehicle.

The body system control unit 12020 controls the operations of various devices mounted in the vehicle body, according to various programs. For example, the body system control unit 12020 functions as control devices for a keyless entry system, a smart key system, power window devices, or various lamps such as headlights, backup lights, brake lights, turn signals, fog lights, and the like. In this case, radio waves emitted from a portable device that substitutes for a key or signals from various switches can be input to the body system control unit 12020. The body system control unit 12020 receives the input of the radio waves or signals and controls door lock devices, power window devices, the lamps, and the like of the vehicle.

The vehicle external information detection unit 12030 detects information on the outside of the vehicle having the vehicle control system 12000 mounted thereon. For example, the vehicle external information detection unit 12030 is connected with an imaging unit 12031. The vehicle external information detection unit 12030 causes the imaging unit 12031 to capture an image of the outside of the vehicle, and receives the captured image. The vehicle external information detection unit 12030 may perform object detection processing or distance detection processing for peoples, cars, obstacles, signs, and letters on the road based on the received image.

The imaging unit 12031 is an optical sensor that receives light and outputs an electrical signal according to the amount of received light. The imaging unit 12031 can also output the electrical signal as an image or as distance measurement information. Furthermore, the light received by the imaging unit 12031 may be visible light or invisible light such as infrared light.

The vehicle internal information detection unit 12040 detects information on the inside of the vehicle. For example, a driver state detection unit 12041 that detects a state of a driver is connected to the vehicle internal information detection unit 12040. The driver state detection unit 12041 includes, for example, a camera that captures an image of a driver, and the vehicle internal information detection unit 12040 may calculate the degree of fatigue or concentration of the driver or may determine whether or not the driver is dozing on the basis of detection information input from the driver state detection unit 12041.

The microcomputer 12051 can calculate a control target value of the driving force generation device, the steering mechanism, or the braking device on the basis of the information on the outside or the inside of the vehicle, the information being acquired by the vehicle external information detection unit 12030 or the vehicle internal information detection unit 12040, and a control command can be output to the drive system control unit 12010. For example, the microcomputer 12051 can perform cooperative control for the purpose of implementing functions of an advanced driver assistance system (ADAS) including collision avoidance or impact mitigation of a vehicle, following traveling based on an inter-vehicle distance, vehicle speed maintenance driving, vehicle collision warning, vehicle lane deviation warning, or the like.

Furthermore, the microcomputer 12051 can perform cooperative control for the purpose of automated driving or the like in which autonomous travel is performed without depending on operations by the driver, by controlling the driving force generator, the steering mechanism, or the braking device or the like on the basis of information about the surroundings of the vehicle, the information being acquired by the vehicle external information detection unit 12030 or the vehicle internal information detection unit 12040.

In addition, the microcomputer 12051 can output a control command to the body system control unit 12020 on the basis of the information acquired about the outside of the vehicle by the vehicle external information detection unit 12030.

For example, the microcomputer 12051 can perform cooperative control for the purpose of preventing glare, such as switching from a high beam to a low beam, by controlling the headlamp according to the position of a vehicle ahead or an oncoming vehicle detected by the vehicle external information detection unit 12030.

The audio/image output unit 12052 transmits an output signal of at least one of sound and an image to an output device capable of visually or audibly notifying a passenger or the outside of the vehicle about information. In the example of FIG. 16, an audio speaker 12061, a display unit 12062, and an instrument panel 12063 are illustrated as output devices. For example, the display unit 12062 may include at least one of an on-board display and a head-up display.

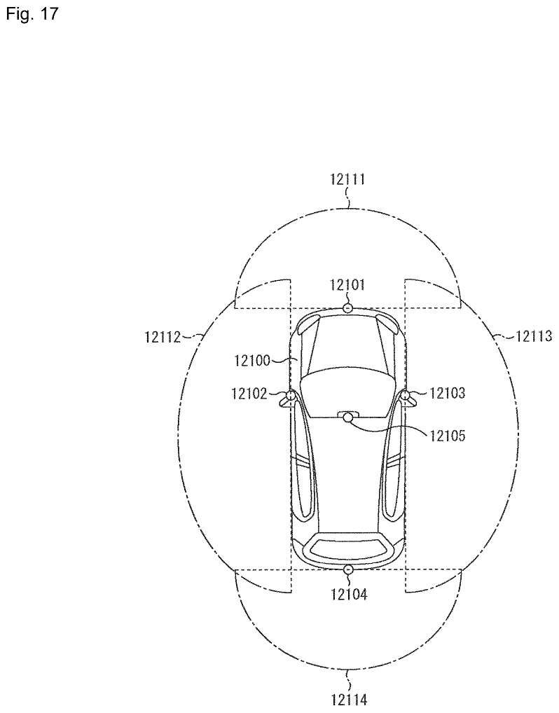

FIG. 17 illustrates an example of installation positions of imaging units 12031. and 12105 as the imaging unit 12031.

For example, the imaging units 12101, 12102, 12103, 12104, and 12105 are provided at positions such as a front nose, side-view mirrors, a rear bumper, a back door, and an upper portion of a windshield in the vehicle interior of the vehicle 12100. The imaging unit 12101 provided at the front nose and the imaging unit 12105 provided in an upper portion of the windshield in the interior of the vehicle mainly capture images ahead of the vehicle 12100. The imaging units 12102 and 12103 provided at the side view mirrors mainly capture images on the sides of the vehicle 12100. The imaging unit 12104 provided at the rear bumper or the back door mainly captures images behind the vehicle 12100.

Front view images captured by the imaging unit 12101 and 12105 are mainly used for detecting a vehicle ahead, pedestrians, obstacles, traffic lights, traffic signs, or lanes or the like.

FIG. 17 illustrates an example of imaging ranges of the imaging units 12101 to 12104. An imaging range 12111 indicates the imaging range of the imaging unit 12101 provided at the front nose, imaging ranges 12112 and 12113 respectively indicate the imaging ranges of the imaging units 12102 and 12103 provided at the side-view mirrors, and an imaging range 12114 indicates the imaging range of the imaging unit 12104 provided at the rear bumper or the back door. For example, by superimposing image data captured by the imaging units 12101 to 12104, a bird's-eye view image viewed from the upper side of the vehicle 12100 can be obtained.

At least one of the imaging units 12101 to 12104 may have the function of acquiring distance information. For example, at least one of the imaging units 12101 to 12104 may be a stereo camera including a plurality of imaging elements or may be an imaging element that has pixels for phase difference detection.

For example, the microcomputer 12051 can extract, particularly, the closest three-dimensional object that is on a traveling path of the vehicle 12100 and that travels at a predetermined speed (e.g., 0 km/h or higher) in the substantially same direction as that of the vehicle 12100, as a preceding vehicle by obtaining a distance to each three-dimensional object in the imaging ranges 12111 to 12114 and a temporal change of this distance (a relative speed with respect to the vehicle 12100) based on the distance information obtained from the imaging units 12101 to 12104. Furthermore, the microcomputer 12051 can set an inter-vehicle distance that needs to be secured in advance in front of the vehicle ahead and can perform automated brake control (also including following stop control) or automated acceleration control (also including following start control). Thus, cooperative control can be performed for the purpose of, for example, automated driving in which autonomous travel is performed without depending on operations by the driver.

For example, the microcomputer 12051 can classify and extract three-dimensional data regarding three-dimensional objects into two-wheeled vehicles, normal vehicles, large vehicles, pedestrians, and other three-dimensional objects such as electric poles based on distance information obtained from the imaging units 12101 to 12104, and can use the three-dimensional data to perform automated avoidance of obstacles. For example, the microcomputer 12051 differentiates surrounding obstacles of the vehicle 12100 into obstacles that can be viewed by the driver of the vehicle 12100 and obstacles that are difficult to view. Furthermore, the microcomputer 12051 determines a collision risk indicating the degree of risk of collision with each obstacle, and when the collision risk is a setting value or more and there is a possibility of collision, outputs an alarm to the driver through the audio speaker 12061 or the display unit 12062, or performs forced deceleration or avoidance steering through the drive system control unit 12010, so that it is possible to perform driving support for collision avoidance.

At least one of the imaging units 12101 to 12104 may be an infrared camera that detects infrared rays. For example, the microcomputer 12051 can recognize a pedestrian by determining whether or not there is a pedestrian in the captured images of the imaging units 12101 to 12104. Such pedestrian recognition is performed by, for example, a procedure of extracting feature points in the captured images of the imaging units 12101 to 12104 that are infrared cameras, and a procedure of performing pattern matching processing on a series of feature points indicating an outline of an object and determining whether or not the object is a pedestrian. When the microcomputer 12051 determines that there is a pedestrian in the captured images of the imaging units 12101 to 12104 and recognizes the pedestrian, the audio/image output unit 12052 controls the display unit 12062 so as to superimpose a square contour line for emphasis on the recognized pedestrian to display. Furthermore, the audio/image output unit 12052 may control the display unit 12062 so as to display an icon indicating a pedestrian or the like at a desired position.

An example of the vehicle control system to which the technique according to the present disclosure can be applied has been described thus far. The technique according to the present disclosure is applicable to the imaging unit 12031 or the like among the configurations described above. Specifically, the technique can be applied to the light detection device 1 in FIG. 1.

(1)

A light detection device including: a first substrate portion having pixels that photoelectrically convert incident light; and
a second substrate portion that is joined to a surface of the first substrate portion opposite to a surface on which the light is incident and has a plurality of elements constituting a readout circuit configured to output a pixel signal based on charges output from the pixels, wherein
a pattern of an insulating film is formed on a bonding surface of the second substrate portion to the first substrate portion.
   (2)

The light detection device according to (1), wherein the insulating film formed on the second substrate portion is composed of multiple types of films.

(3)

The light detection device according to (1), wherein the second substrate portion has element separation portions that separate the plurality of elements.

(4)

The light detection device according to (3), wherein the element isolation portions are formed at a plurality of points of the second substrate portion, and the element separation portions have different depths.

(5)

The light detection device according to (3), wherein a stopper film is formed on the element isolation portion.

(6)

The light detection device according to (1), wherein the element is a transistor.

(7)

The light detection device according to (6), wherein the transistor is composed of a plurality of gate oxide film thicknesses.

(8)

The light detection device according to (1), wherein a plurality of transistors formed in the second substrate portion have different channel depths.

(9)

The light detection device according to (6), wherein the second substrate portion has element isolation portions that separate a plurality of transistors, and a plurality of element formation portions that protrude from the element isolation portions and are arranged in parallel at predetermined intervals, and
at least some of the plurality of transistors formed in the second substrate portion are fin type field effect transistors, each including a gate oxide film and a element formation portions.
   (10)

The light detection device according to (9), wherein the second substrate portion forms a doping layer between the element isolation portion and the element formation portion.

(11)

The light detection device according to (9), wherein at least some of the plurality of transistors formed in the second substrate portion are fin-type field-effect transistors, each including the gate oxide film and the gate electrode that are provided over the top portion and the side portions of each of the element formation portions, and others are planar electric field transistors.

(12)

A method for manufacturing a light detection device, the method including: preparing a first substrate portion having pixels that photoelectrically convert incident light and a second substrate portion having a plurality of elements constituting a readout circuit configured to output a pixel signal based on charges output from the pixels;
forming a pattern of an insulating film on a bonding surface of the second substrate portion to the first substrate portion; and
joining the first substrate portion and the second substrate portion after forming the pattern of the insulating film.
   (13)

An electronic device including a light detection device having: a first substrate portion having pixels that photoelectrically convert incident light; and
a second substrate portion that is joined to a surface of the first substrate portion opposite to a surface on which the light is incident and has a plurality of elements constituting a readout circuit configured to output a pixel signal based on charges output from the pixels, wherein
a pattern of an insulating film is formed on a bonding surface of the second substrate portion to the first substrate portion.

### REFERENCE SIGNS LIST

1, 1A, 1B, 1C, 1D, 1E Light detection device
10 First substrate
11 First semiconductor substrate
11a Front side
12 Sensor pixel
13 Pixel region
14 Fin portion
21b Back side
22 Readout circuit
23 Pixel drive line
24 Vertical signal line
30 Third substrate
31 Third semiconductor substrate
32 Logic circuit
33 Vertical drive circuit
34 Column signal processing circuit
35 Horizontal drive circuit
36 System control circuit
51 High-concentration n type layer (n-type diffusion layer)
52 High-concentration p-type layer (p-type diffusion layer)
53 p-well
54 n-type layer
55 Pixel separation layer
56 p-type layer
57 n-type layer
58, 82 Interlayer insulating film
71 p-well
72 Element isolation layer
73 High-concentration p-type layer
74, 76 Drain portion
75, 77 Source portion
78 High-concentration n-type layer
79 High-concentration n-type layer
41 Planar field-effect transistor
41a Gate electrode
41b Channel portion
41c Gate oxide film
42 Fin-type field-effect transistor
42a Gate electrode
42b1, 42b2 Element formation portion (fin portion)
42c1, 42c2 Gate oxide film
43 Fin-type field-effect transistor
43a Gate electrode
43b Fin portion
43c Gate oxide film
44 Fin-type field-effect transistor
45b Fin portion
45c Gate oxide film
46-1 Fin-type field-effect transistor
46-2 Fin-type field-effect transistor
46a Gate electrode
46b Fin portion
46c Gate oxide film
47 Planar field-effect transistor
47a Gate electrode
47b Channel portion
47c Gate oxide film
48 Planar field-effect transistor
48a Gate electrode
48b Channel portion
48c Gate oxide film
49 Fin-type field-effect transistor
49b1, 49b2 Fin portion
72, 72-1, 72-2, 72-3 Element isolation portion
72a Back-side STI portion
72b1, 72b2, 72b3 Front-side STI portion
83 Contact
84 Through contact
85, 86 Insulating film
87, 88, 89 Engraved portion
91 Liner film
92, 93 Element isolation portion
92a Back side STI portion
92b1, 93c First front-side STI portion
92b2, 93d First front-side STI portion
92c Second front-side STI portion
93a First back-side STI portion
93b Second back side STI portion
94-1, 94-2, 95-1, 95-2 Doping layer
211, 212 Contact through region
911 Nitride film liner
912 Oxide film liner
2201 Imaging device
2202 Optical system
2203 Shutter device
2207 Monitor
2208 Memory
10402 Imaging unit
11000 Endoscopic operation system
11100 Endoscope
11101 Lens barrel
11102 Camera head
11110 Surgical instrument
11111 Pneumoperitoneum tube
11112 Energized treatment tool
11120 Support arm device
11131 Operator (doctor)
11132 Patient
11133 Patient bed
11200 Cart
11201 Camera control unit (CCU)
11202 Display device
11203 Light source device
11204 Input device
11205 Treatment tool control device
11206 Pneumoperitoneum device
11207 Recorder
11208 Printer
11400 Transmission cable
11401 Lens unit
11402, 12031 Imaging unit
11403 Driving unit
11404, 11411 Communication unit
11405 Camera head control unit
11412 Image processing unit
11413 Control unit
12000 Vehicle control system
12001 Communication network
12010 Drive system control unit
12020 Body system control unit
12030 Vehicle external information detection unit
12040 Vehicle internal information detection unit
12041 Driver state detection portion
12050 Integrated control unit
12062 Display unit
12063 Instrument panel
12100 Vehicle
12101, 12102, 12103, 12104, 12105 Imaging unit
12111, 12112, 12113, 12114 Imaging range

1. A light detection device comprising:
a first substrate portion having pixels that photoelectrically convert incident light; and
a second substrate portion that is joined to a surface of the first substrate portion opposite to a surface on which the light is incident and has a plurality of elements constituting a readout circuit configured to output a pixel signal based on charges output from the pixels, wherein
a pattern of an insulating film is formed on a bonding surface of the second substrate portion to the first substrate portion.

2. The light detection device according to claim 1, wherein the insulating film formed on the second substrate portion is composed of multiple types of films.

3. The light detection device according to claim 1, wherein the second substrate portion has element separation portions that separate the plurality of elements.

4. The light detection device according to claim 3, wherein the element isolation portions are formed at a plurality of points of the second substrate portion, and
the element separation portions have different depths.

5. The light detection device according to claim 3, wherein a stopper film is formed on the element isolation portion.

6. The light detection device according to claim 1, wherein the element is a transistor.

7. The light detection device according to claim 6, wherein the transistor is composed of a plurality of gate oxide film thicknesses.

8. The light detection device according to claim 1, wherein a plurality of transistors formed in the second substrate portion have different channel depths.

9. The light detection device according to claim 6, wherein the second substrate portion has element isolation portions that separate a plurality of transistors, and a plurality of element formation portions that protrude from the element isolation portions and are arranged in parallel at predetermined intervals, and
at least some of the transistors formed in the second substrate portion are fin-type field-effect transistors, each including a gate oxide film and a gate electrode formation portions.

10. The light detection device according to claim 9, wherein the second substrate portion forms a doping layer between the element isolation portion and the element formation portion.

11. The light detection device according to claim 9, wherein at least some of the plurality of transistors formed in the second substrate portion are fin type field-effect transistors, each including the gate oxide film and the gate electrode that are provided over the top portion and the side portions of each of the element formation portions, and others are planar electric field transistors.

12. A method for manufacturing a light detection device, the method comprising: preparing a first substrate portion having pixels that photoelectrically convert incident light and a second substrate portion having a plurality of elements constituting a readout circuit configured to output a pixel signal based on charges output from the pixels;
forming a pattern of an insulating film on a bonding surface of the second substrate portion to the first substrate portion; and
joining the first substrate portion and the second substrate portion after forming the pattern of the insulating film.

13. An electronic device comprising a light detection device including:
a first substrate portion having pixels that photoelectrically convert incident light; and
a second substrate portion that is joined to a surface of the first substrate portion opposite to a surface on which the light is incident and has a plurality of elements constituting a readout circuit configured to output a pixel signal based on charges output from the pixels, wherein
a pattern of an insulating film is formed on a bonding surface of the second substrate portion to the first substrate portion.
